(19) United States
(12) Patent Application Publication
(10) Pub. No.: US 2025/0311347 A1
(43) Pub. Date: Oct. 2, 2025

(54) METHOD FOR FORMING A 2D CHANNEL FIELD-EFFECT TRANSISTOR DEVICE

(71) Applicant: IMEC VZW, Leuven (BE)

(72) Inventors: Souvik Ghosh, Holsbeek (BE); Tom Schram, Rixensart (BE); Steven Brems, Kessel-Lo (BE)

(21) Appl. No.: 19/091,630

(22) Filed: Mar. 26, 2025

(30) Foreign Application Priority Data
Mar. 28, 2024 (EP) 24167815.0

(51) Int. Cl. H10D 62/80; H10D 30/00; H10D 30/01; H10D 30/47; H10D 84/01; H10D 84/83

(52) U.S. Cl. CPC H10D 62/883; H10D 30/017; H10D 30/019; H10D 84/0135; H10D 30/481; H10D 30/502; H10D 84/832

(57) ABSTRACT

A method for forming a 2D channel field-effect transistor device is provided. The method includes forming a device layer stack on a substrate. The device layer stack includes lower and upper sacrificial layers and a channel layer of a 2D material. The method further includes embedding the device layer stack in a dummy layer, forming a gate cavity in the dummy layer, and removing the sacrificial layers from the device layer stack by etching the sacrificial material from the gate cavity. After removing the sacrificial layers, the method includes forming an oxide liner along sidewalls of the gate cavity including an oxidation process to oxidize a thickness portion of the dummy layer, forming a gate stack in the gate cavity to surround the channel layer, forming source/drain contact cavities in the dummy layer, forming source/drain contacts in the source/drain contact cavities, and replacing the dummy layer with a dielectric layer.

### CROSS-REFERENCE TO RELATED APPLICATIONS

The present application is a non-provisional patent application claiming priority to European Patent Application No. 24167815.0, filed on Mar. 28, 2024, the contents of which are hereby incorporated by reference.

### FIELD OF THE DISCLOSURE

The present disclosure generally relates to a method for forming a 2D channel field-effect transistor (FET) device.

### BACKGROUND

Modern semiconductor and integrated circuit technology includes Si-based horizontal channel transistors, for example the horizontal or lateral nanosheet field-effect transistor (NSHFET). A NSHFET includes a source, a drain, a channel including one or more nanosheet-shaped horizontally extending channel layers and a gate stack. In a gate-all-around (GAA) design, the gate stack wraps all-around the channel layers.

At aggressively scaled gate lengths of advanced technology nodes, such as below 10 nm gate lengths, it is becoming increasing challenging to further scale Si-based NSHFET devices, e.g., due to reduced channel control. These gate lengths may have sub-5 nm thick Si channels. However, both process-induced Si consumption, short channel effects and the changing behavior of ultrathin Si channels may limit the feasibility of Si channel length and thickness scaling.

In the strive to provide further scaled and more efficient nanosheet devices, there is considerable interest in finding materials to replace Si-based materials as channel material. A promising group of candidate materials for the channel layers is 2D materials. 2D materials, such as transition metal dichalcogenides (TMDs or MX2, where M is a metal such as W or Mo, and where X is a chalcogen such as sulfur or selenide) may offer several improvements over traditional three-dimensional bulk materials like Si. For example, the improvements may be to provide very thin channel layers (e.g., a few monolayers), high electron mobility, precise electrostatic control, and/or favorable on-off ratios, to name a few.

While 2D materials such as TMDs have appealing properties as a channel material in NSHFETs, introducing 2D materials in the integration stacks results in new challenges and considerations for device fabrication.

### SUMMARY

According to an aspect of the present disclosure, there is provided a method for forming a 2D channel field-effect transistor device. The method includes forming a device layer stack on a substrate, the device layer stack including lower and upper sacrificial layers of a sacrificial material and a channel layer of a 2D material arranged between the lower and upper sacrificial layers, wherein the device layer stack extends in a first direction between a first source/drain side and a second source/drain side. The method further includes embedding the device layer stack in a dummy layer of a dummy semiconductor material, forming a gate cavity in the dummy layer, the gate cavity extending in a second direction transverse to the first direction, and exposing the device layer stack along a channel region between the first and second source/drain side. The method also includes removing the sacrificial layers from the device layer stack by selectively etching the sacrificial material from the gate cavity, and, after removing the sacrificial layers, forming an oxide liner along sidewalls of the gate cavity, wherein forming the oxide liner includes performing an oxidation process to oxidize a thickness portion of the dummy layer along the sidewalls of the gate cavity. The method may also include forming a gate stack in the gate cavity to surround the channel layer along the channel region, wherein the oxide liner separates the gate stack from the dummy layer, forming source/drain contact cavities in the dummy layer, on the first and second source/drain sides, forming source/drain contacts in the source/drain contact cavities, in contact with the channel layer, and, after forming the source/drain contacts, replacing the dummy layer with a dielectric layer.

Embedding the device layer stack in a dummy layer of a dummy semiconductor material prior to gate cavity formation and sacrificial layer removal (e.g., “channel release” or “nanosheet release”), instead of an oxide-including inter-layer dielectric (as may be done in fabrication of Si-based devices), provides the sidewalls of the gate cavity to be lined with a (e.g., continuous) oxide liner. The gate cavity, and hence also the gate stack (e.g., subsequently) formed therein, may thus be surrounded by the oxide liner, which may provide a process and isolation margin between the gate stack (e.g., gate metal) and the adjacent structures, for example, the source/drain contacts.

The term “dummy semiconductor material” provides a 3D semiconductor material or bulk semiconductor material (e.g., a non 2D semiconductor material). The dummy semiconductor material may (e.g., typically) be a Si-, Ge- or SiGe-based material, monocrystalline or polycrystalline (e.g., epitaxial Si, Ge or SiGe), or amorphous (e.g., a-Si).

By removing the sacrificial layers from the device layer stack, portions of the sidewalls of the gate cavity initially abutting ends of the sacrificial layers facing the first and second source/drain sides may be exposed. The oxide liner may thus be formed also along these exposed portions of the sidewalls, such that the oxide liner may extend (e.g., continuously) along the sidewalls of the gate cavity and the gate stack facing the first and second source/drain sides. As further set out below, the oxide liner formed may in some embodiments remain along the sidewalls of the gate cavity and the gate stack facing the first and second source/drain sides, after forming the source/drain contacts, and thus further function as an inner spacer, providing a lateral spacing and isolation between the source/drain contacts and the gate stack.

The method herein may be compatible with various species of 2D channel materials. In some example embodiments, the 2D channel material may be a transition metal dichalcogenide, such as molybdenum disulfide, tungsten disulfide, molybdenum diselenide or tungsten diselenide. In other example embodiments the 2D channel material may be black phosphorous.

The term “device layer stack” provides a sequence of layers stacked (e.g., vertically) on top of each other. The sacrificial and channel layers may each be horizontally oriented, e.g., have a main plane of extension parallel to the substrate. The sacrificial and channel layers may for example (e.g., each) be provided in the shape of nanosheets.

The term “gate cavity” herein provides a trench, opening or hole which is formed in the dummy layer adjacent to and along the channel region of the device layer stack such that the device layer stack is exposed along the channel region via the gate cavity. In other words, the gate cavity may expose the device layer stack along the channel region from at least one sidewall thereof such that the device layer stack is accessible via the gate cavity. The gate cavity may, for example, extend across the device layer stack. The gate cavity may thus expose the device layer stack from two opposite sidewalls of the device layer stack. These sidewalls may be referred to as the lateral walls of the device layer stack.

The term “source/drain contact cavity” may correspondingly provide a trench, opening or hole which is formed in the dummy layer adjacent to the device layer stack on the first or second source/drain side thereof. A source/drain contact cavity formed on the first or second source/drain side may, for example, be formed along, and typically expose, a sidewall of the device layer stack facing the given source/drain side. The respective sidewalls of the device layer stack facing the first and second source/drain sides may herein be referred to as the end walls of the device layer stack.

In some example embodiments, the oxidation process is a plasma oxidation process. A plasma oxidation process may be performed in a manner relatively benign to the exposed structures and materials, such that a growth rate of the oxide liner may be controlled and a risk of oxidizing materials which are not to be oxidized (e.g., the channel material, and gate dielectric where present on the channel layer) may be mitigated. The plasma oxidation process may thus be performed to achieve a surface oxidation of the dummy layer, with a target thickness or “depth”. For example, the plasma oxidation process may be a room-temperature plasma oxidation process.

In some example embodiments, the gate cavity includes first and second opposite sidewalls extending along the first and second source/drain sides, respectively, and third and fourth opposite sidewalls connecting the first and second sidewalls at opposite ends of the gate cavity, wherein the oxide liner is formed to extend along each of the first, second, third and fourth sidewalls of the gate cavity. The oxide liner may thus be formed to extend (e.g., continuously) to surround or circumscribe the gate cavity.

In some example embodiments, the third sidewall connects to the first and second sidewalls in respective corner regions of the gate cavity, and the source/drain contact cavities are formed along the first and second sidewalls of the gate cavity, adjacent a respective corner region.

The source/drain contact trenches and contacts may thus be formed at or close to a terminal end or cut in the gate stack. This may be useful to form 2D channel FET devices with small gate extensions. The term “gate extension” may provide the extension of the gate stack (e.g., the gate metal of the gate stack) past a lateral wall of the device layer stack, along the second direction. A “small” gate extension may in this context be a gate extension which is approximately equal to, or within, the margin of alignment errors for forming the source/drain contact cavities.

Hence, where one, or both, of the source/drain contact cavities extend(s) past (and thus along) the respective corner regions of the gate cavity (e.g., due to an alignment error when lithographically patterning the source/drain contact cavities), the oxide liner portion along the respective corner region may still provide a physical and electrical separation between the respective source/drain cavity and corner region.

Designating the portions of the gate stack formed in the respective corner regions of the gate cavity as “corner portions” of the gate stack, the oxide liner portions along the corner portions of the gate stack may (e.g., correspondingly) provide a physical and electrical separation towards the respective source/drain contacts.

In some example embodiments, the device layer stack further includes a gate dielectric layer encapsulating the channel layer, wherein the gate dielectric layer and the channel layer are arranged between the lower and upper sacrificial layers.

The channel layer may thus be surrounded by the gate dielectric layer on (e.g., all) sides. The channel layer may be protected or masked from potentially adverse processing conditions. This may be useful as 2D materials are generally more delicate and hence more prone to damage during processing than silicon.

Moreover, the presence of the gate dielectric layer may provide a structural support for the atomically thin channel layer, hence mitigating a risk of deformation due to sagging (e.g., bending) of the channel layer after the sacrificial layers have been removed to release the channel layer.

In some example embodiments, forming the device layer stack includes forming an initial device layer stack including, in sequence, the lower sacrificial layer, a lower gate dielectric layer portion, the channel layer, an upper gate dielectric layer portion and the upper sacrificial layer, forming a recess in the initial device layer stack by etching back at least the channel layer, and optionally also the gate dielectric layer portions, relative the sacrificial layers, and forming a side gate dielectric layer portion in the recess, wherein the side gate dielectric layer portion connects the upper and lower gate dielectric layer portions to form the gate dielectric layer encapsulating the channel layer.

The initial device layer stack may hence be provided as a vertical stack of layers, e.g., a stack of nanosheets, for example formed using process techniques such as growth, transfer and layer bonding. From this initial device layer stack, the channel layer may be encapsulated by gate dielectric by a combination of lateral selective etch back to form the recess between the sacrificial layers, followed by a deposition step to fill the recess with gate dielectric.

In embodiments where the channel layer is encapsulated by the gate dielectric layer, the method may further include recessing the gate dielectric layer from the source/drain contact trenches to expose a first end portion of the channel layer facing the first source/drain side and a second end portion of the channel layer facing the second source/drain side, wherein the source/drain contacts (e.g., subsequently) are formed in the source/drain contact cavities, in contact with the exposed first and second end portions of the channel layer. The opposite first and second end portions of the channel layer may hence be covered by the gate dielectric until just prior to contact with the source/drain contacts.

In some example embodiments, the method further includes, after removing the sacrificial layers and prior to forming the oxide liner, extending the dummy layer by (e.g., selectively) growing an auxiliary dummy semiconductor material on the dummy layer, including on the sidewalls of the gate cavity. The sidewalls of the gate cavity include a first sidewall extending along the first source/drain side and a second sidewall extending along the second source/drain side. The channel layer includes a first end portion facing the first source/drain side and a second end portion facing the second source/drain side. The auxiliary dummy semiconductor material grows laterally from the first and second sidewalls to surround the first and second end portions of the channel layer from above and below. The thickness portion of the dummy layer oxidized when performing the oxidation process includes a thickness portion of the auxiliary dummy semiconductor material.

The dummy layer may hence be provided with an auxiliary (e.g., additional) thickness portion of auxiliary dummy semiconductor material. The horizontal footprint of the gate cavity may thus be trimmed. For example, the extension along the first direction (e.g., along the channel region) of the spaces above and below the channel layer provided (e.g., defined) by removing the sacrificial layers may thus be reduced from the first and second source/drain sides. As these spaces are to be filled with the gate stack, the auxiliary dummy semiconductor material of the dummy layer allows a gate length of the gate stack to be trimmed. In addition to creating an additional physical separation between the gate stack and the source/drain contact trenches and contacts, the oxidized thickness portion of the auxiliary dummy semiconductor material may surround the first and second end portions of the channel layer from above and below, thus providing (e.g., defining) “inner spacers” towards the first and second source/drain sides.

The auxiliary dummy semiconductor material and the dummy semiconductor material of the initially formed dummy layer (which may be referred to herein as “first dummy semiconductor material”) may be a same material (e.g., a material of a same type). The first and auxiliary semiconductor materials may in other examples be different semiconductor materials. In either case, the auxiliary dummy semiconductor material refers, like the first dummy semiconductor material, to a 3D or bulk semiconductor material (e.g., epitaxial Si, Ge or SiGe, or a-Si), which may be grown or deposited in an area selective manner on the dummy layer.

The area selectivity may be facilitated by that the channel layer is of a 2D channel material, and hence present a (e.g., certain inherent) inertness to the growth of the (non 2D material) auxiliary dummy semiconductor material. The selectivity may also be provided where the channel layer is encapsulated by the gate dielectric layer, in accordance with embodiments set out above, with the additional effect of the channel layer being shielded from direct exposure to the process conditions of the deposition process.

In some example embodiments, the source/drain contact cavities in the dummy layer are separated from the gate stack by the oxide liner and a non-oxidized thickness portion of the auxiliary dummy semiconductor material. The source/drain contact cavities are hence separated from the gate stack by both the inner spacers and non-oxidized auxiliary dummy semiconductor material remaining after the oxidation process.

In some example embodiments, replacing the dummy layer with a dielectric layer includes removing the dummy layer, including the non-oxidized thickness portion, using a selective etching process, and (e.g., subsequently) depositing the dielectric layer.

Hence, remaining non-oxidized dummy material (first and auxiliary) of the dummy layer may be (e.g., selectively) removed and replaced with dielectric material.

In some example embodiments, the method further includes, after forming the source/drain contact cavities and prior to forming the source/drain contacts, recessing the oxide liner from the source/drain contact cavities to expose sidewall portions of the gate stack and (e.g., subsequently) recessing the exposed sidewall portions of the gate stack, to form source/drain recesses, and forming inner spacers covering the recessed sidewall portions of the gate stack and filling the source/drain recesses.

This may represent an alternative to the above discussed embodiments including extending the dummy layer by growth of auxiliary dummy semiconductor material.

The gate length of the gate stack (e.g., along the first direction) may hence be trimmed by, first, a lateral recess of the oxide liner, and then, of the gate stack from the first and second source/drain sides. Inner spacers may then be formed by filling the source/drain recesses with an insulating inner spacer material. The inner spacers may connect with remaining portions of the oxide liner exposed adjoining the source/drain recesses, such that the gate stack may be circumscribed by a continuous composite insulating layer formed by the portions of the oxide liner and the inner spacers.

In some example embodiments, the gate dielectric layer is recessed to expose the first and second end portions of the channel layer after forming the inner spacers. Hence, the end portions of the channel layer may be shielded from the process conditions during the deposition of the inner spacer material, and further during a subsequent etch back of the inner spacer material which may be applied to remove inner spacer material deposited outside the source/drain recesses.

### BRIEF DESCRIPTION OF THE FIGURES

The above, as well as additional, features will be better understood through the following illustrative and non-limiting detailed description of example embodiments, with reference to the appended drawings.

This and other aspects of the present disclosure will now be described in more detail, with reference to the appended drawings.

FIGS. 1a, 1b, and 1c show a top-down view and first and second cross-sectional views of an initial or starting structure of a semiconductor device for a method for forming a 2D channel FET device.

FIGS. 2a, 2b, and 2c show corresponding views of the device structure at a stage of the method according to a first approach.

FIGS. 3a, 3b, and 3c show corresponding views of the device structure at another stage of the method according to the first approach.

FIGS. 4a, 4b, and 4c show corresponding views of the device structure at another stage of the method according to the first approach.

FIGS. 5a, 5b, and 5c show corresponding views of the device structure at another stage of the method according to the first approach.

FIGS. 6a, 6b, and 6c show corresponding views of the device structure at another stage of the method according to the first approach.

FIGS. 7a, 7b, and 7c show corresponding views of the device structure at another stage of the method according to the first approach.

FIGS. 8a, 8b, and 8c show corresponding views of the device structure at another stage of the method according to the first approach.

FIGS. 9a, 9b, and 9c show corresponding views of the device structure at another stage of the method according to the first approach.

FIGS. 10a, 10b, and 10c show corresponding views of the device structure at another stage of the method according to the first approach.

FIGS. 11a, 11b, and 11c show corresponding views of the device structure at another stage of the method according to the first approach.

FIGS. 12a, 12b, and 12c show corresponding views of the device structure at another stage of the method according to the first approach.

FIGS. 13a, 13b, and 13c show corresponding views of the device structure at another stage of the method according to the first approach.

FIGS. 14a, 14b, and 14c show corresponding views of the device structure at another stage of the method according to the first approach.

FIGS. 15a, 15b, and 15c show corresponding views of the device structure at another stage of the method according to the first approach.

FIGS. 16a, 16b, and 16c show corresponding views of the device structure at another stage of the method according to the first approach.

FIGS. 17a, 17b, and 17c show corresponding views of the device structure at another stage of the method according to the first approach.

FIGS. 18a, 18b, and 18c show corresponding views of the device structure at a stage of the method according to a second approach.

FIGS. 19a, 19b, and 19c show corresponding views of the device structure at a stage of the method according to the second approach.

FIGS. 20a, 20b, and 20c show corresponding views of the device structure at a stage of the method according to the second approach.

FIGS. 21a, 21b, and 21c show corresponding views of the device structure at a stage of the method according to the second approach.

FIGS. 22a, 22b, and 22c show corresponding views of the device structure at a stage of the method according to the second approach.

FIGS. 23a, 23b, and 23c show corresponding views of the device structure at a stage of the method according to the second approach.

FIGS. 24a, 24b, and 24c show corresponding views of the device structure at a stage of the method according to the second approach.

FIGS. 25a, 25b, and 25c show corresponding views of the device structure at a stage of the method according to the second approach.

FIGS. 26a, 26b, and 26c show corresponding views of the device structure at a stage of the method according to the second approach.

The figures are schematic, not necessarily to scale, and generally show parts which elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein; rather, these embodiments are provided by way of example. Furthermore, like numbers refer to the same or similar elements or components throughout.

The drawings are schematic and the relative dimensions of illustrated elements, such as layers or other structures, may be exaggerated and not drawn to scale. Rather the dimensions may be adapted for illustrational clarity and to facilitate understanding. When present in the figures, the indicated axes X, Y and Z point in a first direction, a second direction, and a vertical direction, respectively. The first and second directions X, Y may be first and second horizontal directions.

The term “horizontal” refers to a direction parallel to a substrate of the device structure, e.g., parallel to a main surface of the substrate, or equivalently, parallel to an in-plane direction of the layers of the device layer stack. The term “lateral” refers to a direction or orientation along a horizontal plane. The term “vertical” refers to a direction normal or transverse to the substrate, or the direction along which the layers of the device layer stack are stacked. Accordingly, terms indicating relative vertical arrangement of elements, such as “top”, “upper”, “bottom”, “lower” and the like, are to be understood in relation to the vertical direction relative the substrate, or relative the layer stack.

When an element (e.g., a layer or other structure) is referred to as “on” another element, it may be directly on the other element or on one or more intermediate elements on the other element. Conversely, when an element is referred to as “directly on” another element, there may be no intermediate element and the element is thus formed in physical contact or abutment with the other element.

Terms such as “first,” “second,” etc. with reference to elements (e.g., layers or other structures) or process steps may be used herein as labels to facilitate distinguishing between different elements, and may not necessarily imply that such elements or process steps are arranged or performed in that particular order, unless stated otherwise.

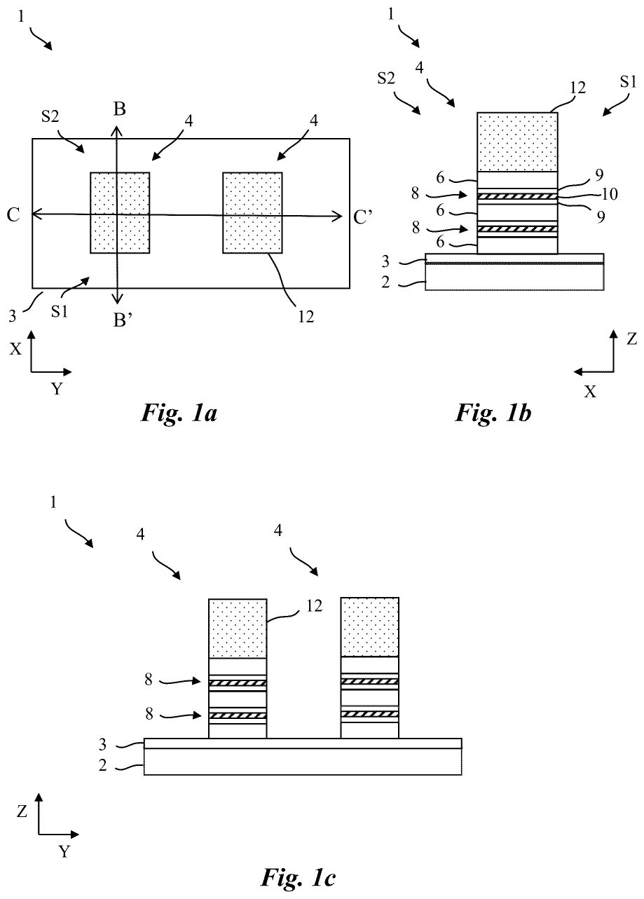

FIGS. 1a-c schematically show a device structure 1 representing an initial or starting structure, to be subjected to process steps disclosed in the following. The device structure 1 includes a substrate 2 and a number of device layer stacks 4 in an initial form, e.g., an initial device layer stack 4. Reference in the following may mainly be made to a single device layer stack 4, however the method may be applied in parallel to a number of corresponding device layer stacks 4 provided on the substrate 2.

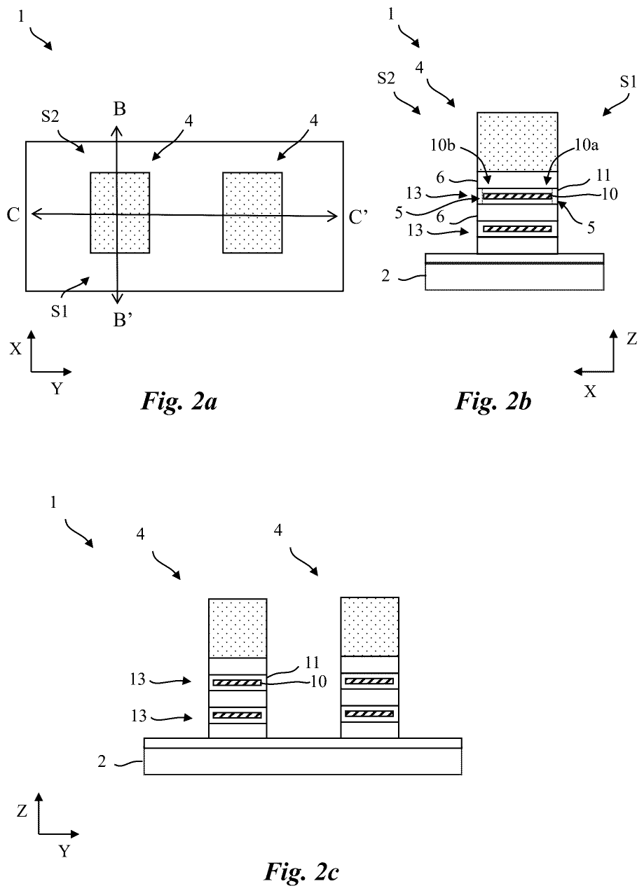

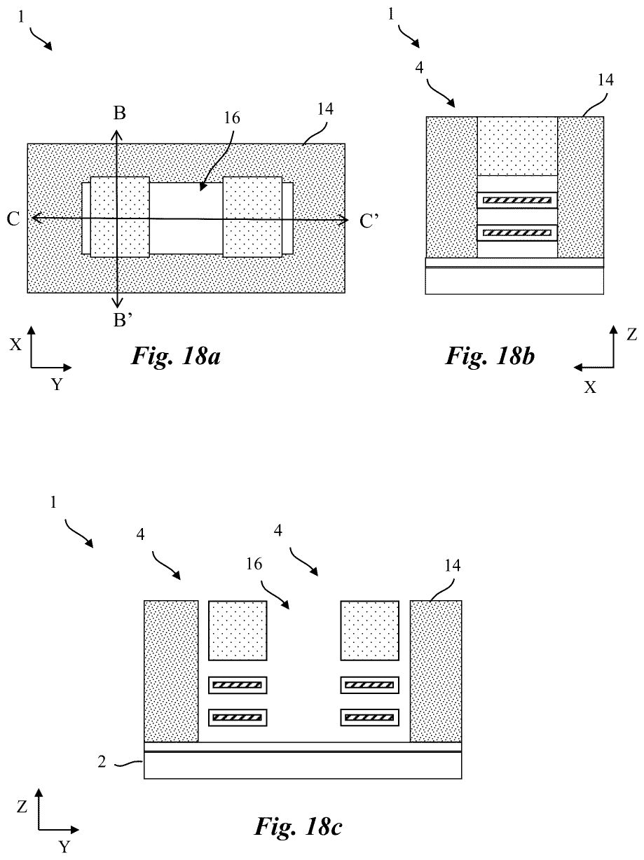

FIG. 1a shows a top-down view of the device structure 1. FIG. 1b shows a first cross-section of the device structure 1 along line B-B′ indicated in FIG. 1a. FIG. 1c shows a second cross-section of the device structure 1 along line C-C′ indicated in FIG. 1a. Description of the respective views of FIGS. 1a-c applies similarly to the subsequent FIGS. 2a, 2b, and 2c through 26a, 26b, and 26c.

In the figures, reference signs S1 and S2 generally designate a first and a second source/drain side, respectively, of the device layer stack 4, that is, the sides of the device layer stack 4 on which the source/drain contacts of the 2D channel FET device are to be formed. The first direction X is thus parallel to an intended channel direction of the device to be formed (which corresponds to the first direction X), for example, from the first source/drain side S1 to the second source/drain side S2.

The device structure 1 includes a substrate 2. The substrate 2 may be a (e.g., conventional) substrate, suitable for semiconductor device processing. The substrate 2 may, for example, be a Si substrate, a Ge substrate or a SiGe substrate. Other examples include a silicon-on-insulator (SOI) substrate, a GeOI substrate or a SiGeOI substrate. A frontside of the substrate 2 may as shown be provided with an insulating layer 3. The insulating layer 3 may serve as a bonding layer for the device layer stack 4, and further function as a bottom isolation layer for the final device.

Unless stated otherwise, a process step described herein as applied to a substrate may be applied to the entire substrate, or to (e.g., only) a portion of the substrate, such as a surface portion of the substrate. Moreover, a process step applied to a substrate, such as a depositing a layer on a substrate, may imply that the process step is applied to a bare substrate or to a substrate already provided with one or more layers or features, such as the insulating layer 3. This applies correspondingly to a structure (e.g., the device layer stack 4) arranged on a substrate (e.g., the substrate 2, with or without the insulating layer 3).

The device layer stack 4 is generally formed in the shape of a fin, e.g., a fin-shaped device layer stack 4. The device layer stack 4 extends between the first and second source/drain sides S1, S2 in the first direction X to provide a length dimension of the device layer stack 4. The device layer stack 4 further has a width dimension along the second direction Y, wherein the length dimension may be either greater, smaller or substantially equal to the width dimension. The device layer stack 4 further has a height dimension along the vertical direction Z by which the device layer stack 4 protrudes above its supporting surface, for example, the frontside of the substrate 2 or, where present, the insulating layer 3. The device layer stack 4 as depicted has two pairs of mutually opposite sidewalls (e.g., vertically oriented sidewalls). The pair of sidewalls facing the first and second source/drain sides S1, S2 may be denoted herein as end walls of the device layer stack 4. The pair of sidewalls of the layer stack 4 connecting the first and second end walls may be denoted as lateral walls of the device layer stack 4.

The (e.g., initial) device layer stack 4 includes a stack of sacrificial layers 6 and sub-stacks or layers or layer units 8. Each sub-stack 8 is arranged between a pair of lower and upper sacrificial layers. Each sub-stack 8 includes a channel layer 10 arranged between a pair of lower and upper gate dielectric layers 9, where the prefix “gate” may signify that the dielectric layers 9 will be incorporated in the gate stack of the finished device. Each pair of sacrificial layers 6 and the gate dielectric and channel layers of the respective sub-stack 8 between the pair of sacrificial layers 6 may, as shown, form a consecutive layer sequence, such as, in a bottom-direction including the lower sacrificial layer 6, the lower gate dielectric layer 9, the channel layer 10, the upper gate dielectric layer 9, and the upper sacrificial layer 6.

Each of the layers 6, 8, 9 of the device layer stack 4 may generally be formed in the shape of a nanosheet.

Each channel layer 10 is formed of a 2D channel material. The 2D channel material may be a transition metal dichalcogenide, such as molybdenum disulfide, tungsten disulfide, molybdenum diselenide or tungsten diselenide. A further example of a 2D material is black phosphorous. The 2D channel material may be deposited using a suitable deposition process, such as chemical vapor deposition (CVD), physical vapor deposition (PVD), atomic layer deposition (ALD) or chemical vapor transfer (CVT). The 2D material may be deposited with a thickness of one to a few monolayers of the 2D material, which may correspond to a thickness in a range of a few tenths of a nanometer to a few nanometers.

Each gate dielectric layer 9 is formed of a gate dielectric material. The gate dielectric material may be a high-k gate dielectric, such as HfO₂, HfSiO, LaO, AI₂O₃ or ZrO₂, or combinations thereof. The 2D material may be deposited using a suitable deposition process, for example, a conformal deposition process such as ALD. The gate dielectric material may be deposited with a thickness in a range of (e.g., about) 1 nm-5 nm, such as an equivalent oxide thickness of 2 nm or less. This thickness range may result in the dielectric layers 9 suitable for use as a gate dielectric in a 2D channel FET device.

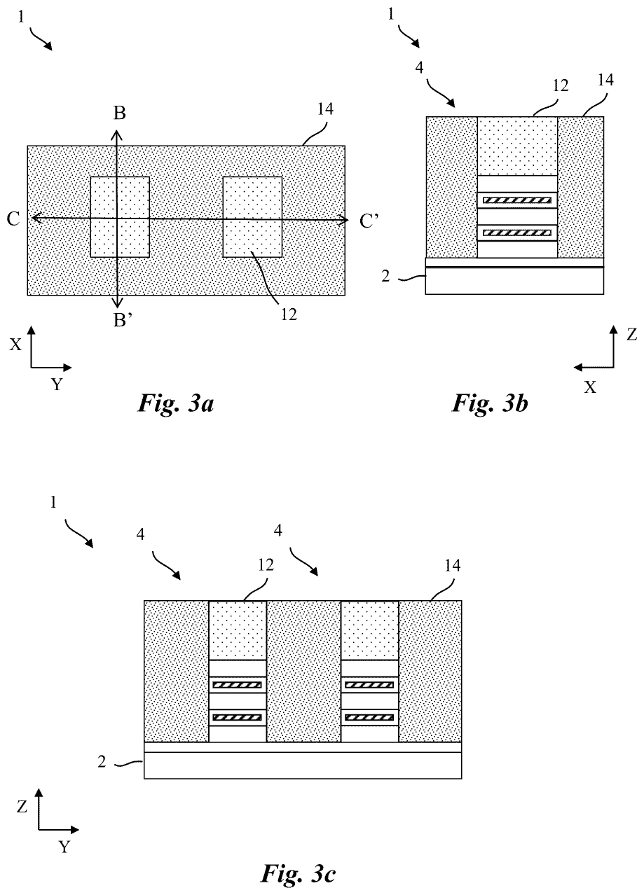

Each sacrificial layer 6 is formed of a sacrificial material. The sacrificial material is chosen as a material etchable selectively to the 2D channel material, the gate dielectric material, and also to a dummy material of a dummy layer 14 (discussed below with reference to FIG. 3), such that the sacrificial material may be etched and/or removed (e.g., selectively) to the channel material, the gate dielectric material and the dummy material (e.g., using an etch process with a (e.g., sufficient) selectivity to the sacrificial material).

The sacrificial material may be a sacrificial dielectric such as, SiO₂, AlN, SiN, TiN, Al₂O₃ or a combination thereof. The sacrificial material may also be a sacrificial semiconductor, e.g., a bulk or 3D semiconductor such as Si, SiGe or Ge, either epitaxial or amorphous. The sacrificial material may be deposited using a suitable deposition processes, such as CVD, PVD or ALD.

The device layer stack 4 may be formed using a combination of process techniques such as layer growth, layer transfer and layer bonding, followed by fin patterning.

For example, a 2D channel layer structure may be formed on the substrate 2. A first layer stack may be formed on a growth wafer (e.g., a sapphire wafer) by growing an initial 2D channel layer on a growth surface of the growth wafer, forming an initial gate dielectric layer of the gate dielectric material on a first major surface of the initial 2D channel layer, and forming an initial sacrificial layer of the semiconductor (e.g., the non 2D semiconductor) on a major surface of the initial gate dielectric layer.

The first layer stack may then be bonded to the substrate 2 with the initial sacrificial layer facing the substrate 2.

The growth wafer may (e.g., subsequently) be debonded from the layer stack. The debonding may be achieved using a mechanical debonding process. To further reduce the bonding force between the initial channel layer and the growth wafer, and thus facilitate a mechanical debonding, the interface between the initial channel layer and the growth wafer may optionally be intercalated by water (e.g., de-ionized water or ultra-pure water to mitigate a risk of contaminating the initial channel layer).

Some bulk/3D semiconductors may allow the sacrificial layer to induce stress at an interface between the growth wafer and the initial channel layer, which may facilitate debonding using a mechanical debonding process.

After debonding the growth wafer from the first layer stack, a second initial gate dielectric layer of the gate dielectric material may be formed on a second major surface of the initial 2D channel layer, followed by a further sacrificial layer on a major surface of the second initial gate dielectric layer.

A second layer stack may further be performed in a similar manner as the first layer stack, such as growing an initial 2D channel layer on a growth surface of a second growth wafer (e.g., sapphire), forming an initial gate dielectric layer of the gate dielectric material on a first major surface of the initial 2D channel layer, and forming an initial sacrificial layer of the semiconductor (e.g., the non 2D semiconductor) on a major surface of the initial gate dielectric layer.

The second layer stack may then be bonded to the first layer stack such that the second initial sacrificial layer and the initial sacrificial layer of the second layer stack are (e.g., directly) bonded to each other to form a common second initial sacrificial layer.

The second growth wafer may thereafter be debonded from the second layer stack in a manner corresponding to the debonding of the first growth wafer such that the second growth wafer is released from the initial channel layer of the second layer stack.

These process steps may be repeated a number of times to obtain a 2D channel layer structure including a (e.g., desired) number of initial channel layers.

The outlined process above is an example, and that another sequence of process steps allowing a 2D channel layer structure with the disclosed composition of layers may be employed. For example, each initial 2D channel layer may be grown on a respective growth wafer, be exfoliated from the growth wafer (e.g., using a thermal release tape), and transferred to the substrate 2. The thermal release tape may then be removed, wherein a first initial gate dielectric layer, an initial sacrificial layer, and then a second initial gate dielectric layer may be deposited thereon. This may be repeated a number of times.

The stack of layers of the 2D channel layer structure may (e.g., subsequently) be patterned to form a plurality of fin-shaped device layer stacks 4, as shown in FIGS. 1a, 1b, and 1c. Suitable single- or multiple-patterning techniques used for fin patterning may be used. Reference sign 12 indicates a hard mask (e.g., a nitride- or oxide-based hard mask layer) remaining on top of each device layer stack 4 after patterning. The hard mask 12 may, as discussed herein, remain on (e.g., each) device layer stack 4 during at least a subset of the process steps.

As shown in the example, the device layer stack 4 includes three sacrificial layers 6 and two sub-stacks 8. This is an example and a device layer stack may include fewer or greater number of sacrificial layers and sub-stacks; however, the device layer may include at least one pair of lower and upper sacrificial layer, and a sub-stack arranged between the pair of sacrificial layers. For conciseness, reference will in the following mainly be made to a single pair of sacrificial layers 6, a single channel layer 10, and a single pair of dielectric layers 9 (from FIG. 2 and onwards a single dielectric layer 11). The following discussion may apply correspondingly to additional such layers of the device layer stack 4.

In FIGS. 2a, 2b, and 2c, the channel layer 10 has been encapsulated on all sides by a gate dielectric layer 11. Each sub-stack 8 has thus been processed to form a respective sub-stack 13 including a respective gate dielectric layer 11 and a respective channel layer 10 encapsulated by the dielectric layer 11. The sub-stack 13 is similar to the sub-stack 8 arranged between the lower and upper sacrificial layers 6. The encapsulating dielectric layer 11 may, among others, protect or mask the channel layer 10 from potentially adverse processing conditions during the below described process steps.

As schematically indicated in FIG. 2b, the channel layer 10 may be encapsulated by the gate dielectric layer 11 by forming a recess 5 in the device layer stack 4 by etching back at least the channel layer 10, and optionally also the gate dielectric layer portions 9, relative the sacrificial layers 6.

The recess 5 may be formed by laterally etching the channel layer 10, and optionally the gate dielectric layers 9, from the end walls and lateral walls of the device layer stack 4. The lateral etch back may be achieved by an isotropic etching process. The etching process may be a suitable dry etching process or wet etching process allowing selective etching of the 2D channel material, and optionally the gate dielectric material, without causing (e.g., appreciable) etch back of the sacrificial layers 6.

A side gate dielectric layer portion may (e.g., subsequently) be formed in the recess 5, wherein the side gate dielectric layer portion connects the (e.g., recessed) upper and lower gate dielectric layer portions 9 to form the gate dielectric layer 11 encapsulating the channel layer 10. The side gate dielectric layer portion may, similar to the gate dielectric layers 9, be formed of a high-k dielectric material, such as provided in the examples of high-k dielectrics mentioned above. The high-k dielectric material of the side gate dielectric layer portion may be a same material species as the gate dielectric layers 9 to obtain a continuous gate dielectric layer 11 with (e.g., substantially uniform) properties along the encapsulated channel layer 10. The side gate dielectric layer portion may be formed by depositing the gate dielectric material conformally (e.g., using ALD) to fill the recess 5. Portions of the gate dielectric material deposited outside the recess 5 may (e.g., subsequently) be removed by etching the gate dielectric material using an isotropic etch until the sacrificial layers 6 are exposed along the end walls and lateral walls of the device layer stack 4.

Since the device layer stack 4 is exposed along its full circumference, the recess 5 is formed in each of the end walls and the lateral walls of the device layer stack 4. The recess 5 is thus formed as a circumferentially extending recess. Correspondingly, the side gate dielectric layer portion of the gate dielectric layer 11 extends circumferentially about the channel layer 10, along each of the end walls and the lateral walls of the device layer stack 4. For example, the gate dielectric layer 11 as depicted covers each of a first end portion 10a of the channel layer 10 facing the first source drain side S1, and a second end portion 10b of the channel layer 10 facing the second source drain side S2.

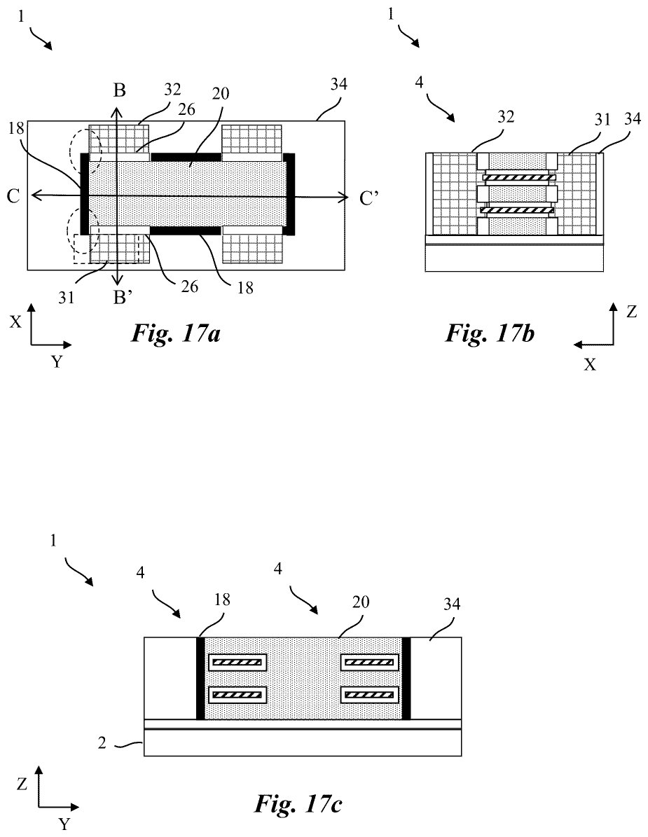

Process steps of a method of a first approach which may be applied to the device structure 1 including the substrate 2 and the device layer stack 4, as shown in FIGS. 2a-c, will now be disclosed with reference to FIGS. 3a-c through FIGS. 17a-c.

In FIGS. 3a-c, the device layer stack 4 has been embedded in a dummy layer 14 of a dummy semiconductor material.

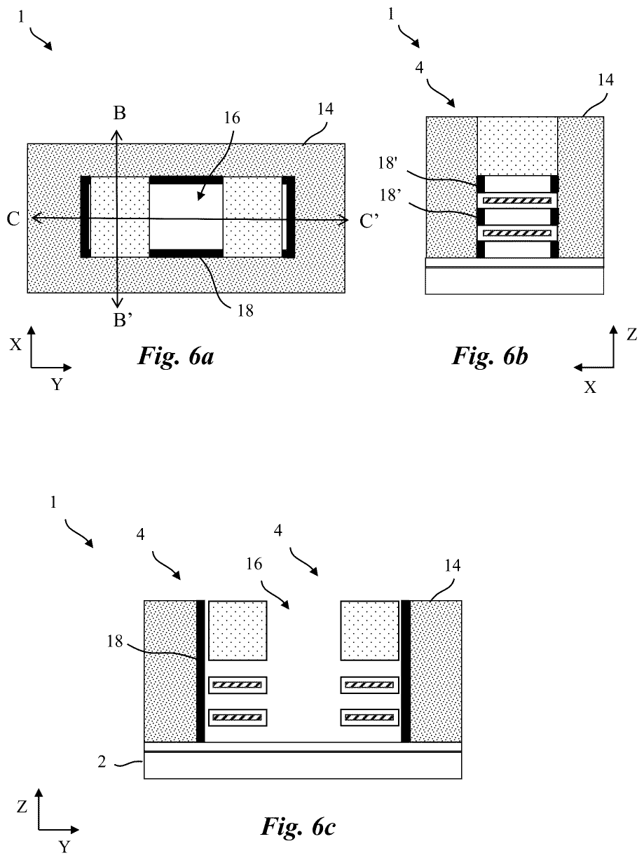

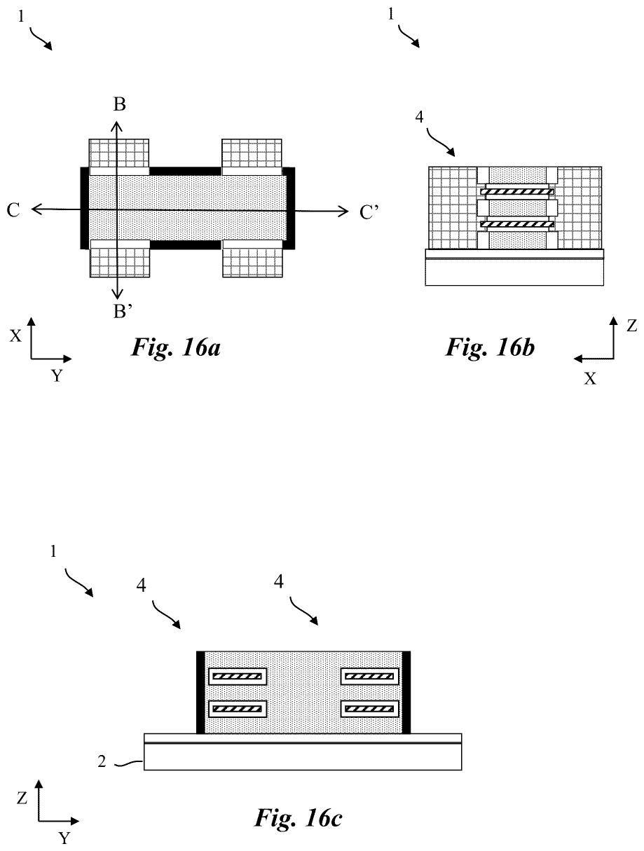

The dummy semiconductor material may be a Si-, Ge- or SiGe-based material, deposited in monocrystalline polycrystalline (e.g., epitaxial Si, Ge or SiGe), or amorphous (e.g., a-Si) form. The dummy semiconductor material may be chosen as a suitable bulk or 3D semiconductor having a lower oxidation temperature and lower oxidation rate than the 2D channel material, such that an oxide liner 18 (see FIGS. 6a-c) may be formed using an oxidation process in an area selective manner along the dummy layer 14, without causing appreciable co-deposition on other surfaces or oxidation of 2D channel material. The dummy semiconductor material may further be chosen to be etchable with a relatively high selectivity towards (e.g., typical) high-k gate dielectrics, thus facilitating the subsequent removal of the dummy layer 14, see FIGS. 16a-c. A dummy semiconductor material of a-Si may for example be a choice as it may be deposited quickly and inexpensively.

The dummy semiconductor material may be deposited using a suitable deposition process, such as CVD or PVD. The deposited dummy semiconductor material may (e.g., subsequently) be planarized (e.g., by chemical mechanical polishing (CMP)) to produce a planarized top surface flush with a top surface of the hard mask 12, as shown in FIGS. 3a-c.

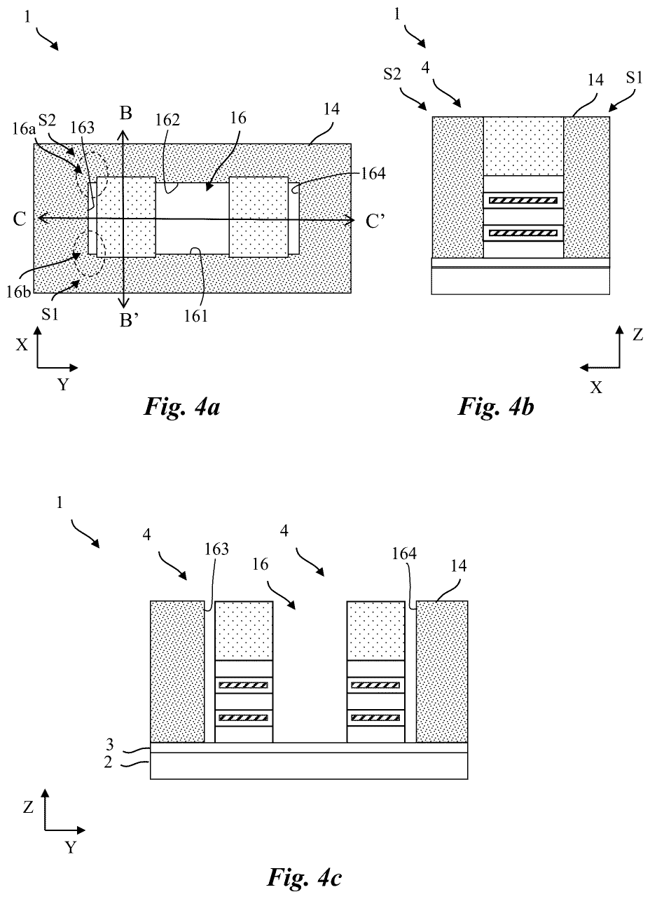

In FIGS. 4a-c, a gate cavity or gate trench 16 has been formed in the dummy layer 14. The gate cavity 16 extends in the second direction Y transverse to the first direction X, and exposes the device layer stack 4 along a channel region between the first and second source/drain sides S1, S2.

The gate cavity 16 includes first and second opposite sidewalls 161, 162 extending along the first and second source/drain sides S1, S2, respectively. The first and second sidewalls 161, 162 may, as shown, extend along the second direction Y. The gate cavity 16 further includes third and fourth opposite sidewalls 163, 164 connecting the first and second sidewalls 161, 162 at opposite ends of the gate cavity 16. The third and fourth sidewalls 163, 164 may, as shown, extend along the first direction X.

The third sidewall 163 connects to the first and second sidewalls 161, 162 in respective corner regions 16a, 16b of the gate cavity 16. Correspondingly, the fourth sidewall 164 connects to the first and second sidewalls 161, 162 in corresponding respective corner regions 16a, 16b at the opposite end of the gate cavity 16.

The sidewalls 161, 162, 163, 164 may, as shown, be substantially vertically oriented (e.g., extend along the vertical direction Z).

The gate cavity 16 may be formed by a lithography and etching process. A suitable anisotropic etching process, wet or dry, with a (e.g., sufficient) selectivity towards the dummy semiconductor material may be used. The etch may be stopped on the substrate 2 or, where present, the insulating layer 3.

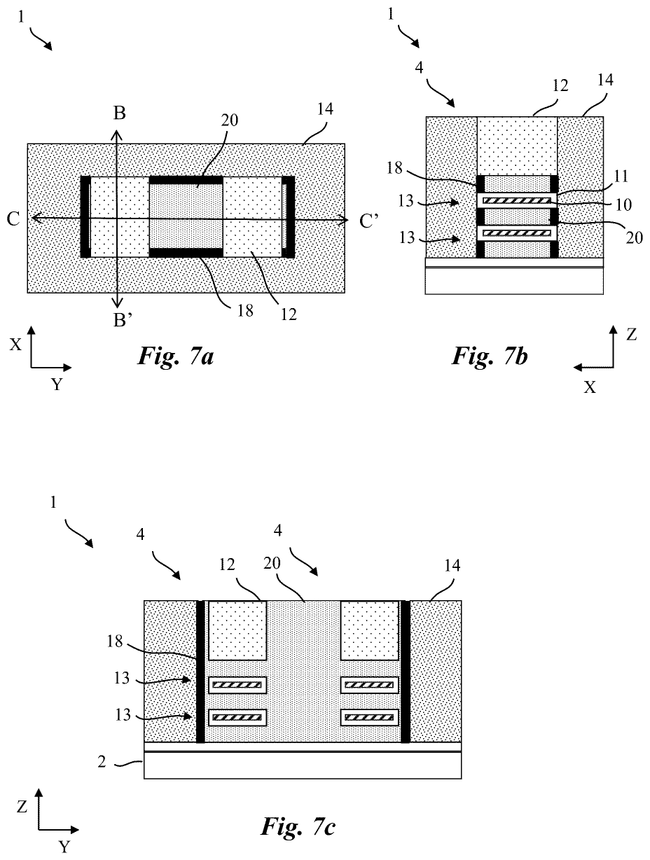

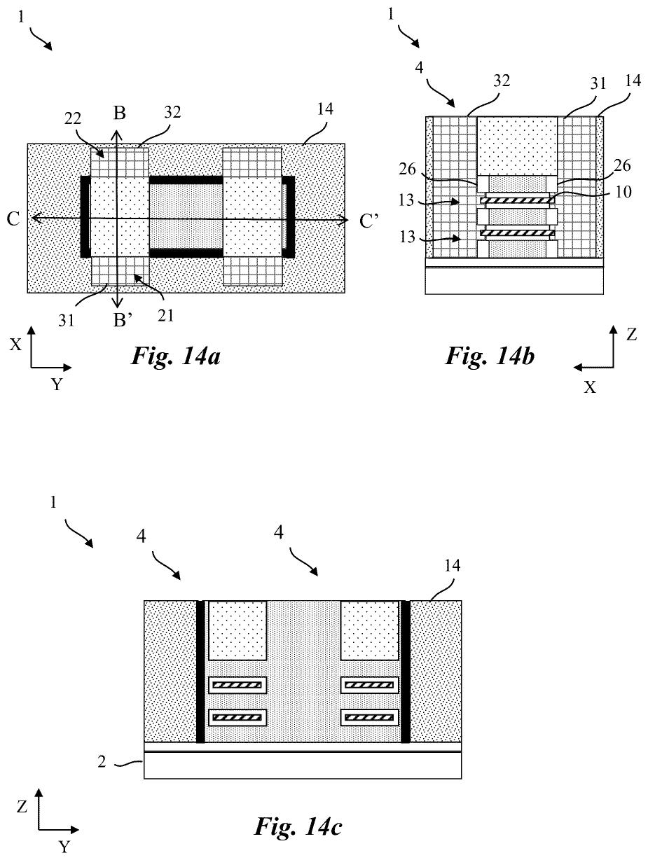

In the illustrated example, the gate cavity 16 is formed with a width dimension (e.g., along the first direction X) smaller than the length dimension of the device layer stack 4. Thereby, the end walls of the device layer stack 4 may remain covered by the dummy layer 14. A difference between the width dimension of the gate cavity 16 and the length dimension of the device layer stack 4 may translate to an increased physical separation between the (e.g., subsequently) formed gate stack 20 (see FIGS. 7a-c) and source/drain contacts 21, 22 (see FIGS. 14a-c).

In the illustrated example, the gate cavity 16 extends across the device layer stack 4 so as to expose both lateral walls of the device layer stack 4. This facilitates forming of a device GAA gate stack. As further shown, the gate cavity 16 may extend across more than one device layer stack 4, such as two device layer stacks 4. This facilitates forming two relatively closely spaced 2D channel FETs having a common or shared gate stack, as will be shown in the following.

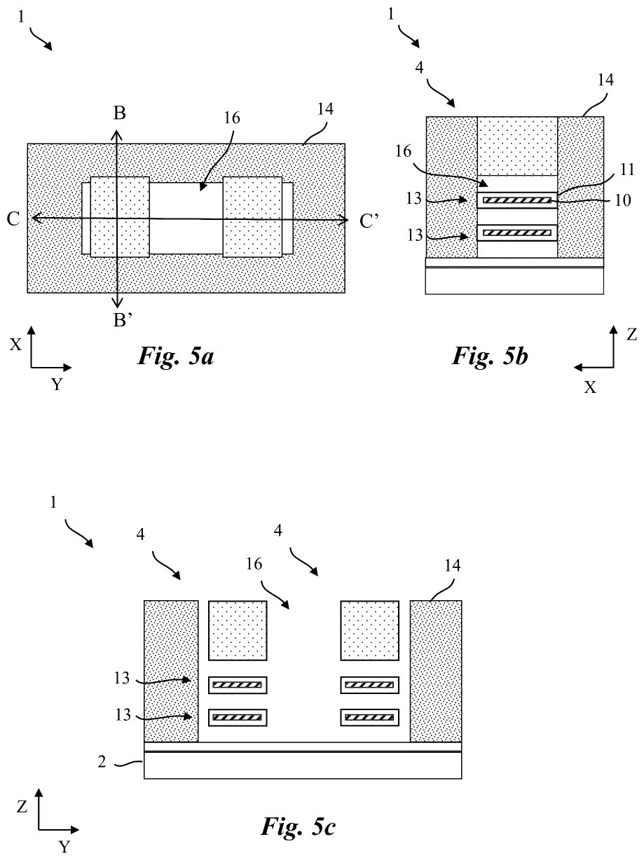

In FIGS. 5a-c, the sacrificial layers 6 have been removed from the device layer stack 4 by selectively etching the sacrificial material from the gate cavity 16. The sacrificial layers 6 may thereby be removed selectively to the sub-stacks 13. Each sub-stack 13, including the channel layer 10 and the gate dielectric layer 11, may thus be released and become suspended within the gate cavity 16, between the first and second source/drain sides S1, S2.

The sub-stacks 13 may, for example, be suspended by abutting portions of the dummy layer 14. Here, a further effect of forming the gate cavity 16 with a smaller width dimension than the length dimension of the device layer stack 4 may be appreciated, in that a greater difference may increase a contact interface between the sub-stacks 13 and the dummy layer 14 and hence more reliable securing of the sub-stacks 13.

If further securing of the sub-stacks 13 is desired, an additional process step may be applied to the device layer stack 4 after the stage shown in FIGS. 2a-c, and prior to forming the dummy layer 14, by recessing the sacrificial layers 6 from the end walls of the device layer stack 4. The recessing may be achieved by etching back the sacrificial layers 6 from the end walls using a suitable isotropic etching process, selective to the sacrificial material. To prevent recessing of the sacrificial layers 6 along the lateral walls of the device layer stack 4, the lateral walls of the device layer stack 4 may be masked by a temporary mask layer during the etch back. After the recessing, the dummy layer 14 may be formed to protrude into the recesses thus formed in the device layer stack 4, above and below the sub-stacks 13, and thus provide a further securing thereof.

By removing the sacrificial layers 6, the gate cavity 16 is, as shown, extended into the device layer stack 4 above and below the sub-stacks 13 includes the channel layer 10 and the encapsulating gate dielectric layer 11.

The sacrificial layers 6 may be removed using a suitable etching process with a (e.g., sufficient) selectivity towards the sacrificial material, relative the gate dielectric material, such that the sacrificial layers 6 may be removed without causing appreciable etching or removal of the gate dielectric layer 11.

During and subsequent to the release process, the dielectric layer 11 encapsulating the channel layer 10 may mask the channel layer 10 and mitigate a risk of sagging of the channel layer 10.

FIGS. 6a-c show the device structure 1 after the sacrificial layers 6 have been removed and (e.g., subsequently) an oxide liner 18 has been formed along the sidewalls of the gate cavity 16.

The oxide liner 18 is formed by performing an oxidation process adapted to oxidize a thickness portion of the dummy layer 14 along the sidewalls of the gate cavity 16.

The oxidation process may be a plasma oxidation process using O₂ as oxidizing agent. The oxidation process may be performed at a relatively low temperature to mitigate a risk of causing oxidation of the 2D channel material. For example, the oxidation process may be a room-temperature plasma oxidation process. A further example is an atmospheric-pressure plasma conducted at a temperature of 50° C. or lower.

During the plasma process, the oxidizing ambient may react with a thickness portion of the dummy semiconductor material of the dummy layer 14. The term “thickness portion” here provides a depth of the surface oxidation caused by the oxidation process (e.g., as seen along a local surface normal of the dummy layer 14).

The rate of oxidation, and thus growth rate of the oxide liner 18, may be varied by controlling parameters, such as reactor temperature and concentration of oxidizing ambient in the reactor ambient.

The oxide liner 18 thus formed, as shown, may extend (e.g., continuously) along the sidewalls of the gate cavity 16 (e.g., the sidewalls 161, 162, 163, 164 as shown in FIG. 4a). This includes the surface portions of the dummy semiconductor material of the first and second sidewalls 161, 162 exposed when removing the sacrificial layers 6, as indicated by portions 18′ in FIG. 6b.

FIGS. 6a-c show no growth of the oxide liner 18 along the top surface of the dummy layer 14. This may be achieved by preserving at least parts of the mask used to form the gate cavity (e.g., trench) 16 during the oxidation process. The top surface of the dummy layer 14 may thus be masked from the oxidizing ambient and hence not oxidized by an appreciable extent. The mask may (e.g., subsequently) be removed to reveal the non-oxidized top surface of the dummy layer 14. This is an example, and it is also possible to remove the mask prior to the oxidation process, wherein the oxide liner 18 may be formed also along the top surface of the dummy layer 14.

In FIGS. 7a-c, a gate stack 20 has been formed in the gate cavity 16. The gate stack 20 surrounds the channel layer 10 and the gate dielectric layer 11 of each sub-stack 13 along the channel region. The gate stack 20 is separated from the dummy layer 14 by the oxide liner 18.

Since the gate dielectric layer 11 in the illustrated example already is present on each channel layer 10, the gate stack 20 in this example refers to the conductive gate body, or gate electrode. Accordingly, the gate stack 20 may include one or more conductive layers, such as one or more gate metal layers, however highly doped polysilicon is also a possibility.

Examples of gate metal layers include one or more function metals (e.g., Ti, TiAl, TiAlC, TiN, TaN, Mo, MoN, deposited by ALD), and/or a gate fill metal such as W, Mo, Al, Co or Ru. The gate fill metal may for example be deposited by CVD, ALD or PVD. After deposition, the deposited gate metal layer(s) may be planarized (e.g., by CMP and/or metal etch back) to remove overburden metal deposited outside the gate cavity 16, and thus arrive at the device structure 1 as shown in FIGS. 7a-c. The planarization may, for example, be stopped on the top surface of the hard mask 12.

Since the gate cavity 16, as discussed above, in the illustrated example has been formed to extend across the device layer stack 4 and thus expose both lateral walls of the device layer stack 4, the gate stack 20 correspondingly has a non-zero gate extension past both lateral walls of the device layer stack 4. The gate stack 20 hence provides a GAA with respect to the channel layers 10.

The dimension of the gate extension past (e.g., any of) the lateral walls of the device layer stack 4 may substantially correspond to the corresponding extension of the gate cavity 16 minus “trimming” of the gate cavity 16 caused by the growth of the oxide liner 18.

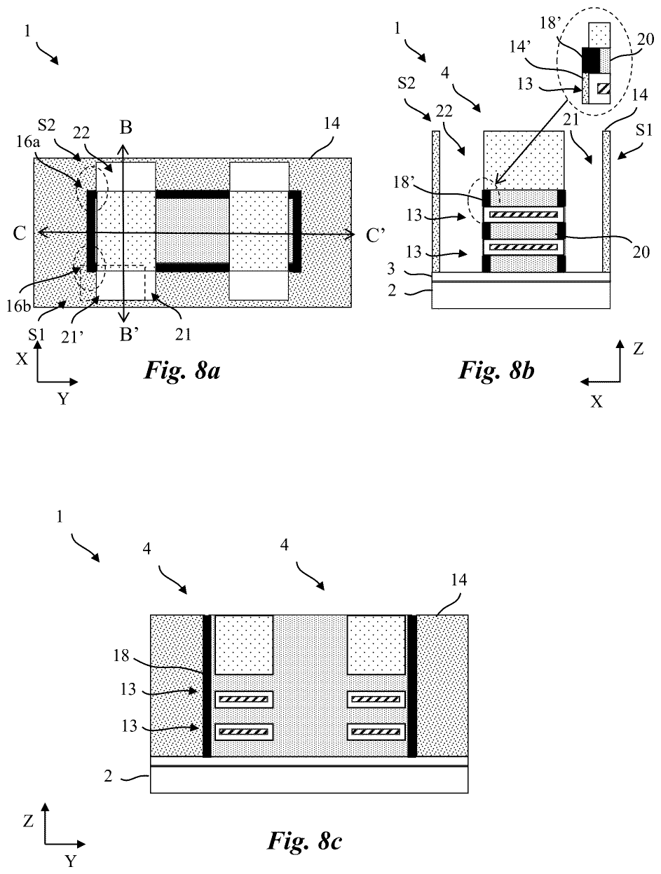

In FIGS. 8a-c, source/drain contact cavities 21, 22 have been formed in the dummy layer 14, on the first and second source/drain sides S1, S2, respectively.

The gate cavity 16 may be formed by a lithography and etching process. A suitable etching process, isotropic or anisotropic, wet or dry, with a (e.g., sufficient) selectivity towards the dummy semiconductor material may be used. The etch may be stopped on the substrate 2 or, where present, the insulating layer 3.

The first source/drain contact cavity 21 is formed along and exposes the end wall of the device layer stack 4 facing the first source/drain side S1. The second source/drain contact cavity 22 is formed along and exposes the end wall of the device layer stack 4 facing the second source/drain side S2.

In the illustrated example, the source/drain contact cavities 21, 22 are each formed with a width dimension (along the second direction Y) corresponding to, or substantially equal to, the width dimension of the device layer stack 4. Wider source/drain contact cavities may provide a greater contact interface between the channel layer 10 and the (e.g., subsequently) formed source/drain contacts.

Due to the presence of the oxide liner 18, the source/drain contact cavities 21, 22 may as shown at no location expose the gate stack 20. For example, from the first and second source/drain sides S1, S2 the source/drain contact cavities may be separated from the gate stack 20 by the oxide liner portions 18′.

In the illustrated example, the source/drain contact cavities 21, 22 are (e.g., each) formed to be adjacent or neighboring to a respective one of the corner regions 16a, 16b but may not extend past the corner regions 16a, 16b. However, the roadmap for advanced technology nodes envisages devices with (e.g., very) small (e.g., by way of example about 5 nm or less, such as 2 nm or less, or 1 nm or less) or even zero gate extensions. The oxide liner 18 may be appreciated, as a smaller gate extension reduces the tolerance for alignment errors when forming the source/drain contact cavities 21, 22. For example, an edge placement error during lithography for patterning the source/drain contact cavities 21, 22 may result in one or both of the source/drain cavities 21, 22 displaced so as to extend past the respective corner regions 16a, 16b. This is indicated schematically in FIG. 8a by the dashed rectangular outline representing an outline of such a displaced first source/drain cavity extending past the corner region 16a. Accordingly, absence of the oxide liner 18 along the third sidewall 163 of the gate cavity (e.g., trench 16 and the corresponding sidewall of the gate stack 20, may present a risk of exposing the gate stack 20 from the source/drain contact trench 21′. This may in turn result in a risk of an electrical short, or insufficient spacing and isolation margin, between the gate stack 20 and the source/drain contact (e.g., subsequently) formed therein.

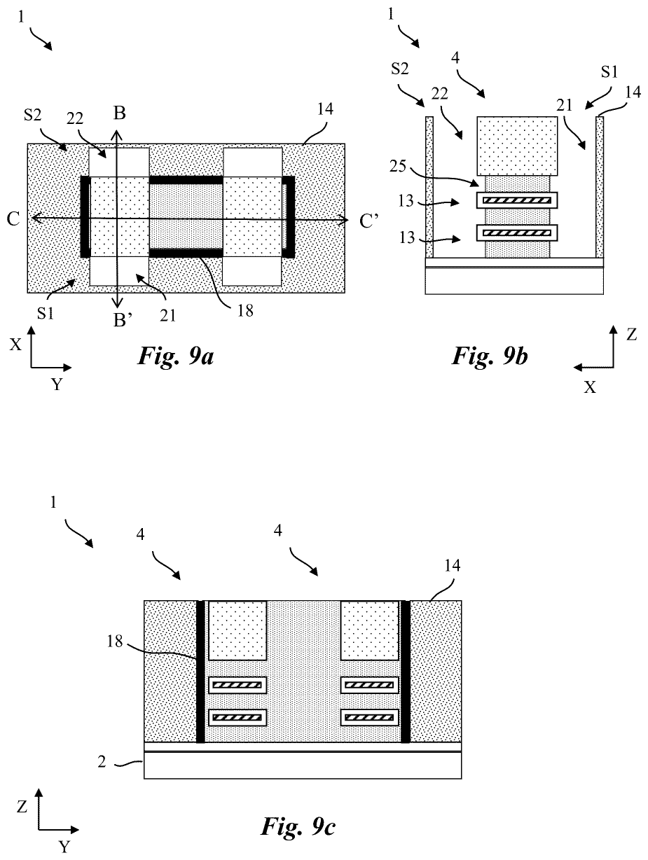

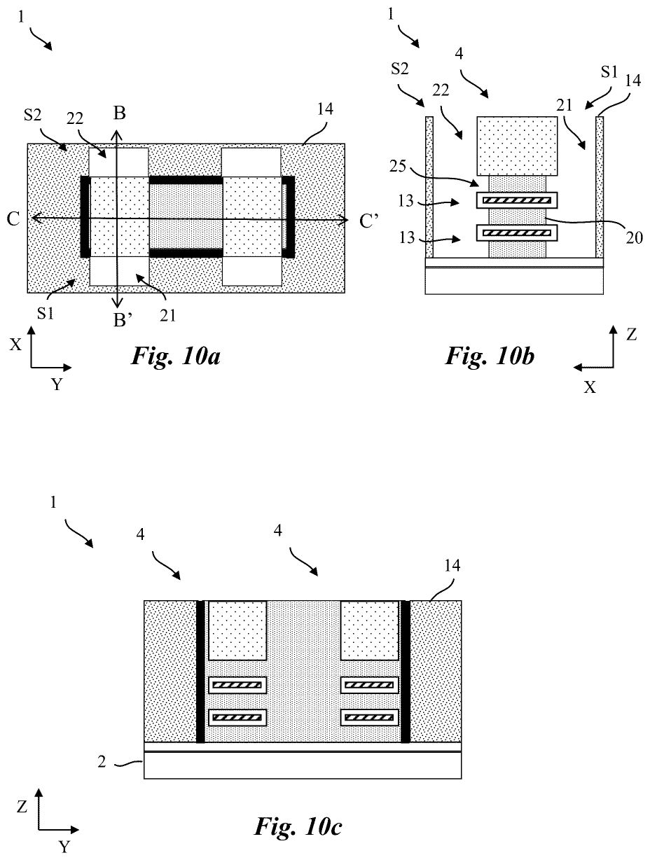

FIGS. 9a-c and FIGS. 10a-c show process steps performed after forming the source/drain contact cavities 21, 22 and prior to forming the source/drain contacts 31, 32, for forming recesses 25 for inner spacers, herein termed “source/drain recesses 25”.

In FIGS. 9a-c the oxide liner 18, for example, the oxide liner portions 18′ shown in FIG. 8b, has/have first been recessed from the source/drain contact cavities 21, 22 to expose sidewall portions of the gate stack 20. In FIGS. 10a-c, the exposed sidewall portions of the gate stack 20 have (e.g., subsequently) been recessed to form the source/drain recesses 25.

The oxide liner 18 and the gate stack 20 may (e.g., each) be recessed using (e.g., respective) suitable isotropic etching process, wet or dry, with a (e.g., sufficient) etch selectivity towards the respective materials.

The recessing may serve to provide a further increased physical spacing between the (e.g., subsequently) formed source/drain contacts 31, 32 and the gate stack 20, beyond the spacing already provided by the oxide liner 18.

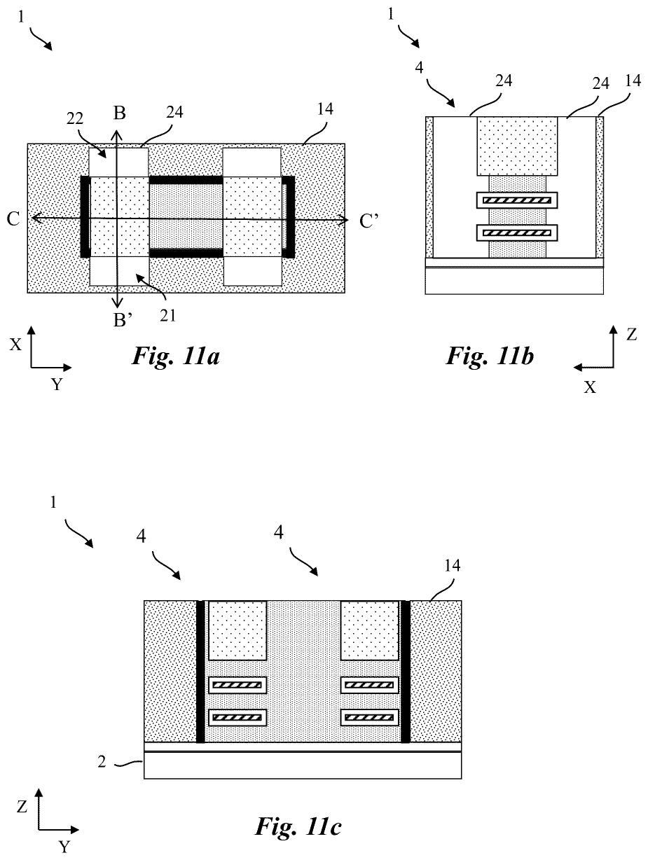

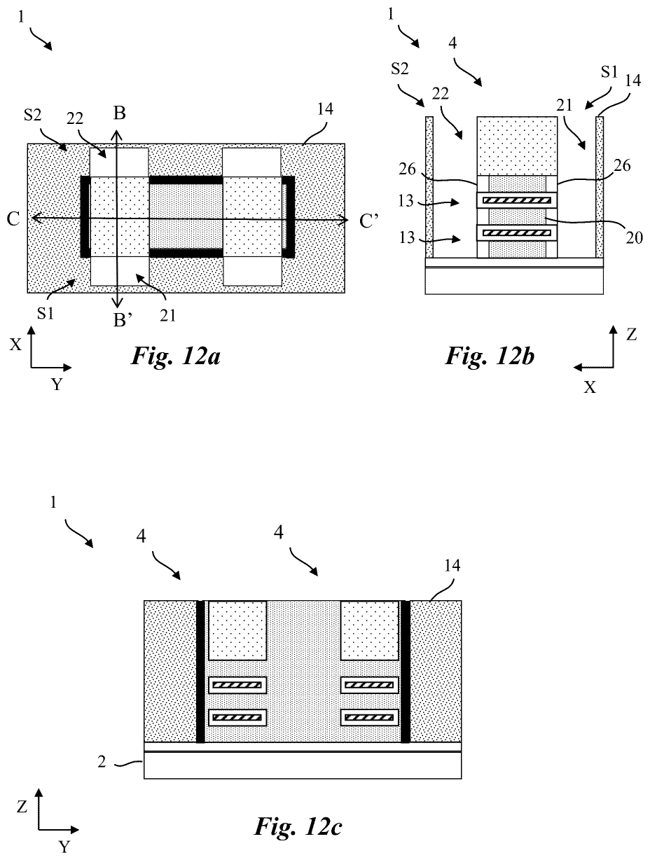

FIGS. 11a-c and FIGS. 12a-c show process steps for forming inner spacers 26 covering the recessed sidewall portions of the gate stack 20 and filling the source/drain recesses 25.

In FIGS. 11a-c, an insulating inner spacer material 24 has been deposited to fill the source/drain contact trenches 21, 22 and the source/drain recesses 25. A suitable dielectric material used as inner spacer material may be used (e.g., oxides and/or nitrides, typically of a low-k). The inner spacer material 24 may be deposited using a suitable process such as CVD or PVD.

In FIGS. 12a-c, the inner spacer material 24 has been etched such that the inner spacer material deposited outside the source/drain recesses 25 is removed but preserved in the source/drain recesses 25 to form the inner spacers 26. An etching process allowing the inner spacer material 24 to be etched anisotropically in a top-down direction (e.g., along the vertical direction Z) may be employed.

In another example, the inner spacer material 24 may instead be deposited conformally (e.g., by ALD) to fill the source/drain recesses 25. Portions of the inner spacer material 24 deposited outside the source/drain recesses 25 may (e.g., subsequently) be removed by etching (e.g., an anisotropic etch or an isotropic etch).

The removed portions of the oxide liner 18′ may be replaced with inner spacers 26 adjoining the remaining the portions of the oxide liner 18 not removed during the oxide liner recess step. However, due to the preceding recess of the gate stack 20, a thickness of the inner spacers 26 (e.g., along the first direction X) may exceed that of the oxide liner 18.

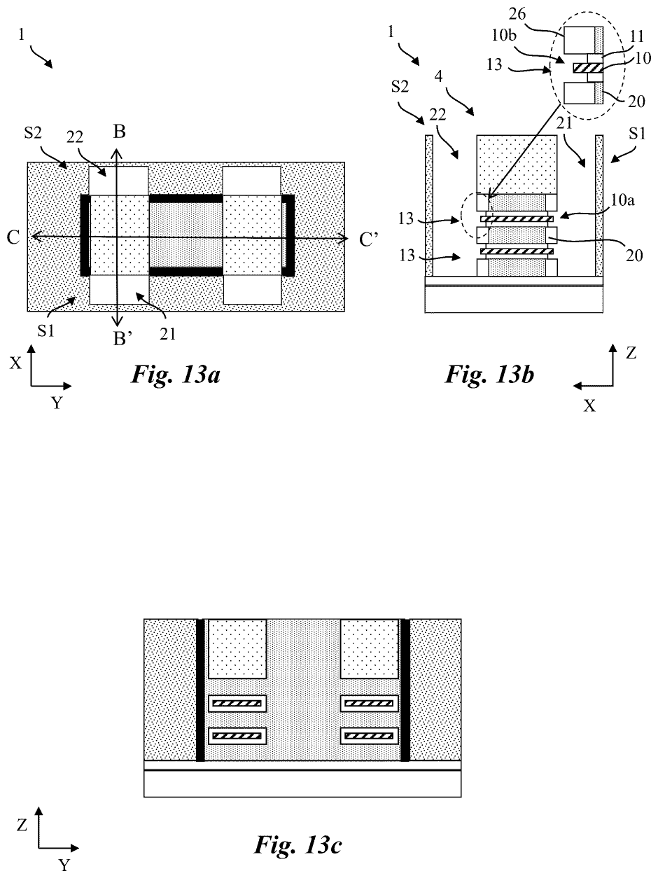

In FIGS. 13a-c, the gate dielectric layer 11 has, after forming the inner spacers 26, been recessed to expose the first and second end portions 10a, 10b of the channel layer 10. The channel layer 10 may thus be prepared for the subsequent contacting with the source/drain contacts 31, 32.

The gate dielectric layer 11 may be recessed using an etching process etching the gate dielectric material selective to the inner spacer material and the 2D channel material. For example, a suitable isotropic etching process, wet or dry, with a (e.g., sufficient) selectivity towards the gate dielectric material may be used.

As shown in the enlargement of the inset of FIG. 13b, the gate dielectric layer 11 may be recessed such that upper and lower surface portions of the end portions 10a, 10b are exposed. This provides forming the source/drain contacts 31, 32 as wrap-around contacts, with a larger contact interface. However, a side contact approach is also possible. The side contact approach may stop the recess of the gate dielectric layer 11 as soon as end portions 10a, 10b of the channel layer 10 are exposed. The depth of the recessing of the gate dielectric layer 11 should not expose the gate stack 20.

As shown in the enlargement of the inset of FIG. 8b, there may, following the forming of the source/drain contact cavities 21, 22, remain trace amounts of dummy semiconductor material 14′ on the end surfaces of the sub-stacks 13 facing the respective trenches (e.g., cavities) 21, 22. This may be due to the portions of the dummy layer being shadowed by a slight lateral protrusion of the oxide liner portions 18′ relative the end surfaces of the sub-stacks 13. Hence, the recessing of the gate dielectric layer 11 may be preceded by a recess (e.g., lateral etch back) of such trace amounts of dummy semiconductor material 14′. A suitable isotropic etching process, wet or dry, with a (e.g., sufficient) selectivity to the dummy semiconductor material may be used.

In FIGS. 14a-c, source/drain contacts 31, 32 have been formed in the source/drain contact cavities 21, 22. The source/drain contacts 31, 32 have been formed in contact with the channel layer 10, for example, in contact with the end portions 10a, 10b exposed in the preceding step.

The source/drain contacts 31, 32 may be formed by one or more conductive contact materials, such as metals. Examples of contact metals include Ti, Bi, Sb, Ni, Pd pure or alloyed. The contact metal may generally be selected in accordance with the conductivity type of the device being formed (e.g., N-type or P-type). A remaining portion, e.g., a portion not filled by the preceding contact metal(s) may be filled by a fill metal, for example W, Al, Au or Ag. The contact metal(s) may be deposited using a suitable deposition process, such as PVD, CVD and/or ALD. After deposition, overburden contact metal may be recessed by chemical mechanical polishing (CMP) and/or metal etch back, and thus arrive at the device structure 1 as shown in FIGS. 14a-c.

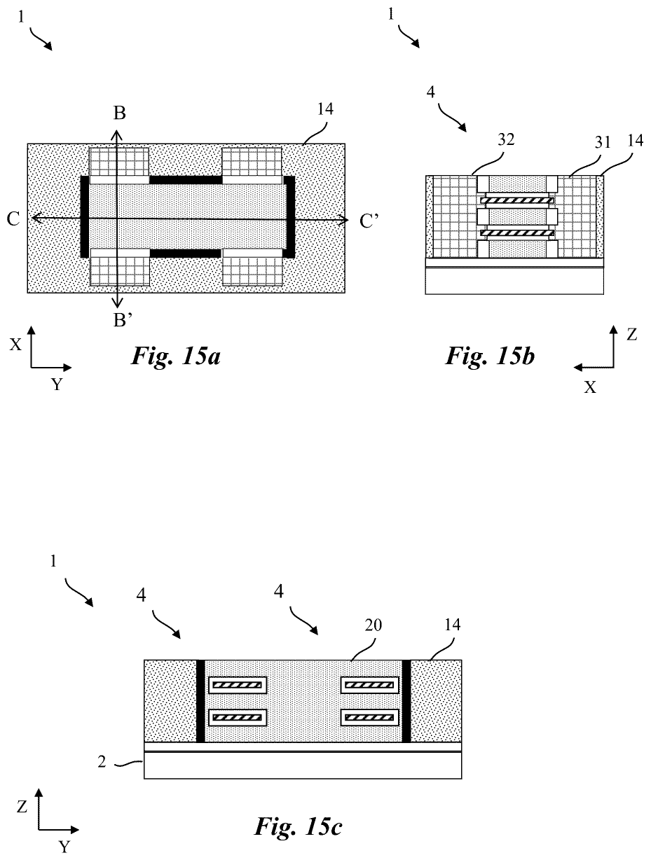

In FIGS. 15a-c the device structure 1 has been subjected to a planarization process, to reduce a height of the source/drain contacts 31, 32 and the gate stack 20 to a final target height. The hard mask 12 may during this step also be removed.

FIGS. 16a-c and FIGS. 17a-c depict process steps for replacing the dummy layer 14 with a dielectric layer 34.

In FIGS. 16a-c, the dummy layer 14 has been removed by etching away remaining portions of the dummy semiconductor material. An isotropic etch process, wet or dry, with a (e.g., sufficient) selectivity to the dummy semiconductor material may be used.

In FIGS. 17a-c, the dielectric layer 34 has been formed by depositing one or more dielectric materials over the device structure 1 to embed the source/drain contacts 31, 32 and/or the gate stack 20 therein. The dielectric layer 34 may be formed of a suitable dielectric materials used as inter-layer dielectric, such as silicon oxide or some other low-k dielectric. Further, the deposited dielectric materials may be planarized (e.g., CMP and/or etch back) to bring the top surface of the dielectric layer 34 flush with the top surface of the source/drain contacts 31, 32 and the gate stack 20.

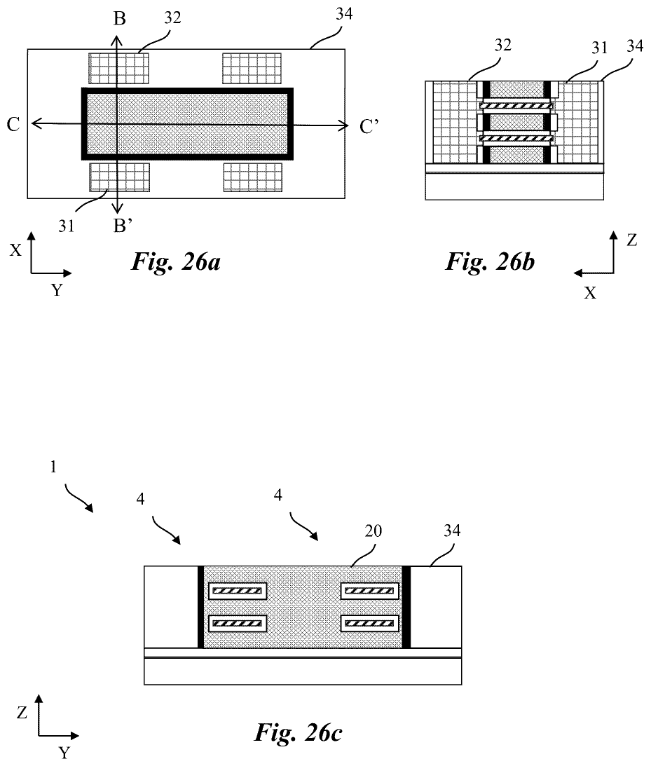

Process steps of a method of a second approach (e.g., a second example) which may be applied to the device structure 1 including the substrate 2 and the device layer stack 4, as shown in FIGS. 2a-c, will now be disclosed with reference to FIGS. 17a-c through FIGS. 26a-c.

The second approach generally proceeds similar to the first approach up to and including the channel release. FIG. 13a accordingly shows the device structure 1 and the device layer stack 4 at a stage after the sacrificial layers 6 have been removed.

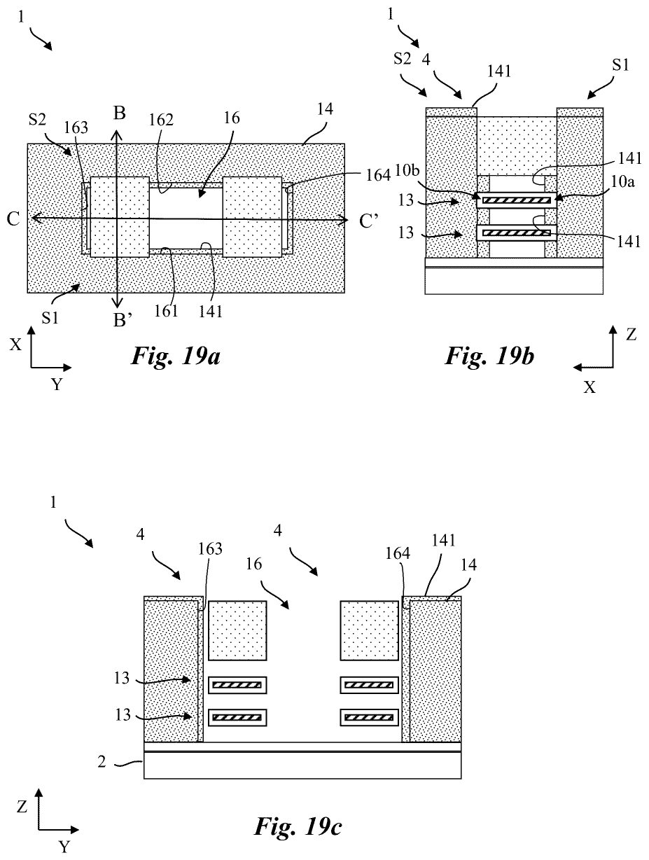

FIGS. 19a-c show the device structure 1 after removing the sacrificial layers 6 and prior to forming the oxide liner 18, wherein the dummy layer 14 further has been extended by selectively growing an auxiliary dummy semiconductor material 141 on the dummy layer 14, including on the first through fourth sidewalls 161, 162, 163, 164 of the gate cavity 16.

As shown, the auxiliary dummy semiconductor material 141 may thus grow laterally from the first and second sidewalls 161, 162 to surround the first and second end portions 10a, 10b of the channel layer 10 of (e.g., each) sub-stack 13 from above and below.

The auxiliary dummy semiconductor material 141 may be of a same or similar species as the (e.g., first) dummy semiconductor material of the dummy layer 14. For example, the auxiliary dummy semiconductor material 141 may be epitaxial Si, Ge or SiGe, or a-Si, or some other 3D or bulk semiconductor which may be grown or deposited in an area selective manner on the dummy layer 14. Selective deposition by PVD, CVD or ALD is possible. In either case, the auxiliary dummy semiconductor material 141 may seed from exposed surface portions of the first dummy semiconductor material of the dummy layer 14.

The auxiliary dummy semiconductor material 141 may be formed with a thickness corresponding to a desired separation between the gate stack 20 and the source/drain contacts 31, 32 which are to be formed. For example, the auxiliary dummy semiconductor material 141 may be formed with a thickness in a range of 1 to a few nm, such as 1-3 nm (e.g., depending also on a length dimension of the channel layer 10).

In either case, growth of the auxiliary dummy semiconductor material 141 on the sidewalls 161, 162, 163, 164 of the gate cavity (e.g., trench) 16 results in a trimming of the length and width dimensions of the gate cavity (e.g., trench) 16.

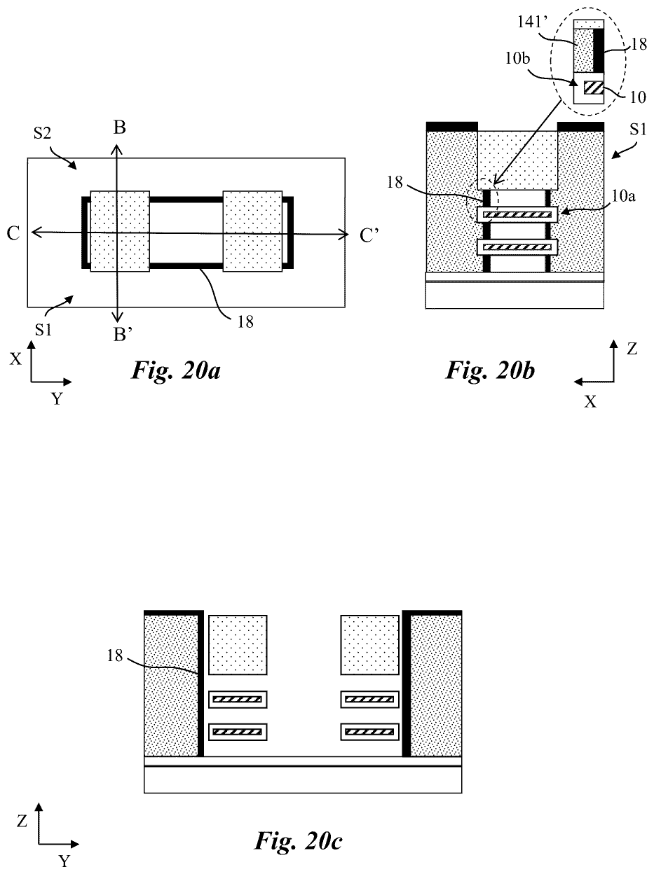

In FIGS. 20a-c an oxide liner 18 has been formed along the sidewalls of the gate cavity 16. For example, the oxide liner 18 is in FIG. 20a (e.g., only) indicated along the sidewalls of the gate cavity 16 and omitted from the top surface of the dummy layer 14. The oxide liner 18 in the second approach generally corresponds to and may be formed in the corresponding manner to the oxide liner 18 in the first approach, e.g., using an oxidation process. However, in contrast to the first approach where the oxide liner 18 is formed by oxidizing a thickness portion of the first dummy semiconductor material, the oxide liner 18 in the second approach is formed by oxidizing a thickness portion of the further auxiliary dummy semiconductor material 141 of the (e.g., extended) dummy layer 14.

In FIGS. 20a-c, forming of the oxide liner 18 along the top surface of the dummy layer 14 is shown. FIGS. 19a-c further show a deposition of auxiliary dummy semiconductor material 141 on the top surface of the dummy layer 14. If either of these results are not desired, it is (discussed herein above with respect to the first approach) possible, as shown in FIGS. 6a-c, to preserve at least a portion of a mask used to form the gate cavity 16. The mask may be removed subsequent to completing the oxidation process.

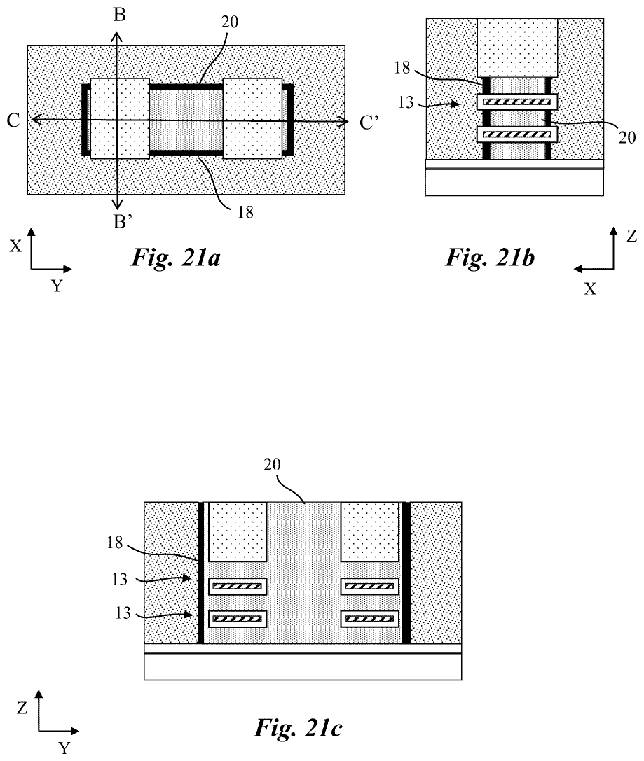

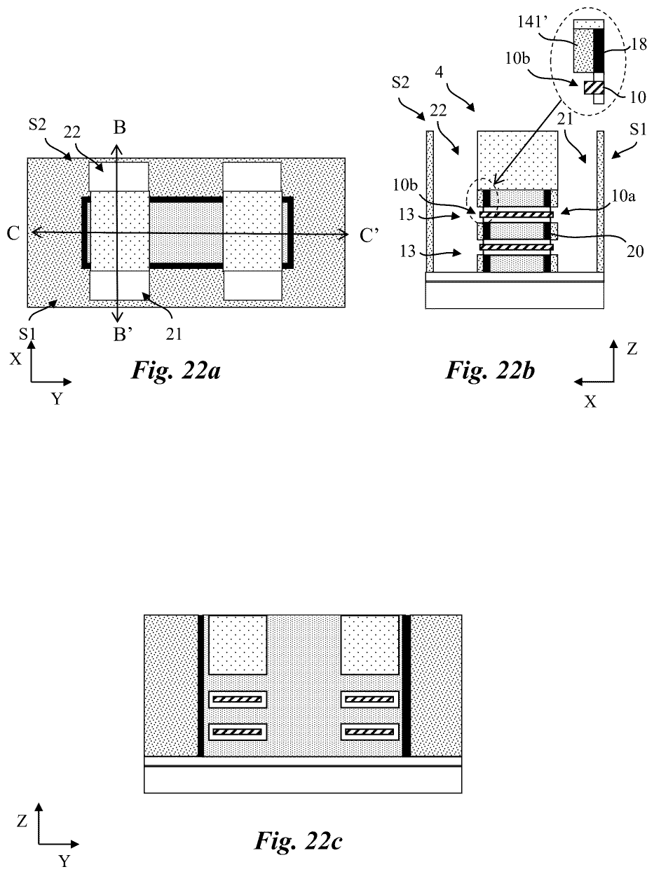

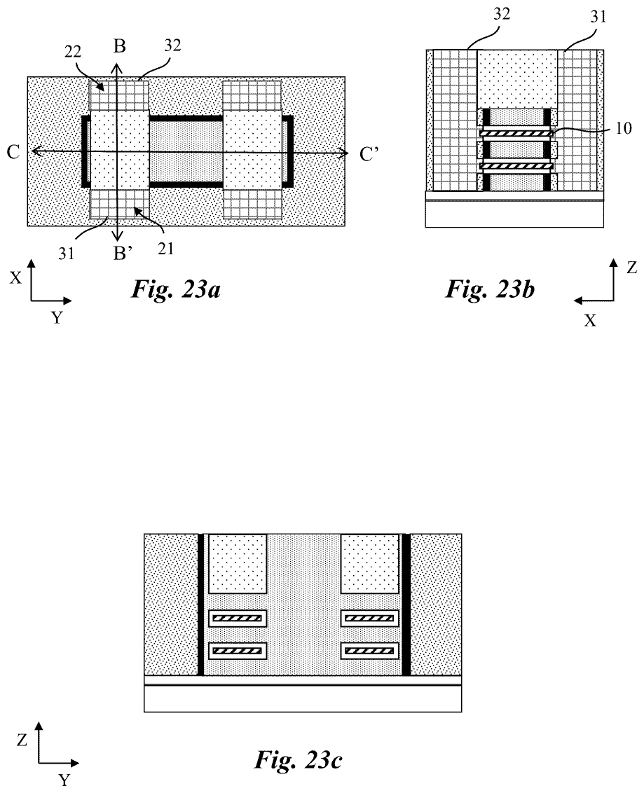

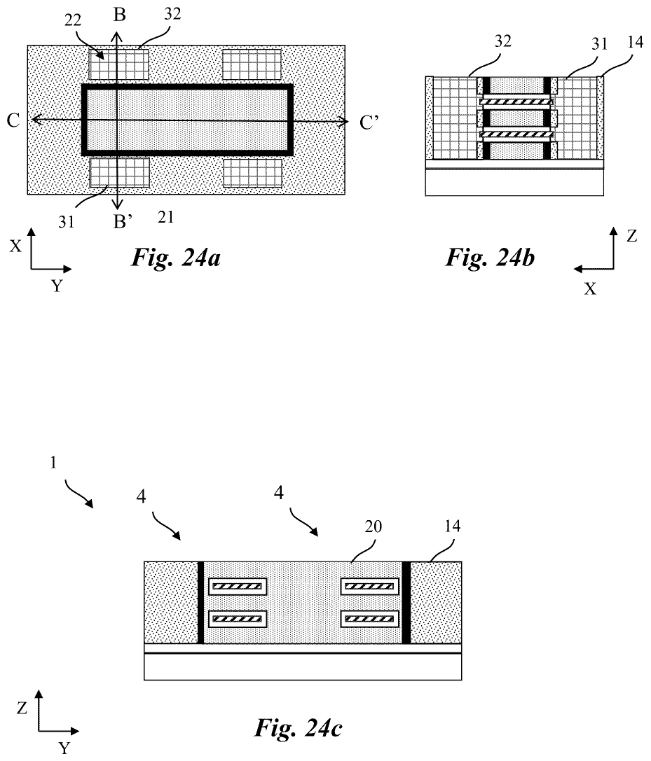

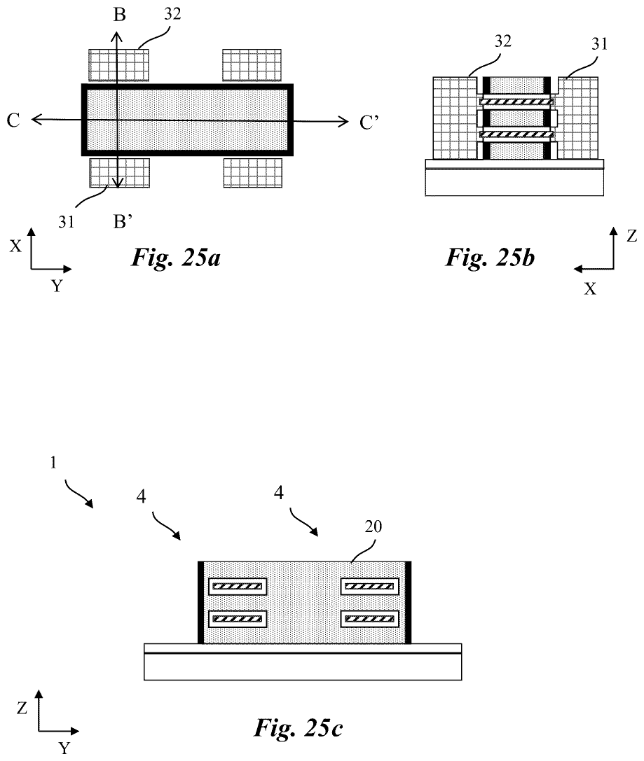

After forming the oxide liner 18, the method of the second approach generally proceeds similarly to the first approach, e.g., by forming the gate stack 20 (FIGS. 21a-c), forming source/drain contact cavities 21, 22 (FIGS. 22a-c), forming source/drain contacts 31, 32 (FIGS. 23a-c), planarizing the device structure 1 (FIGS. 24a-c), and replacing the dummy layer 14 with a dielectric layer 34 (FIGS. 25a-c and FIGS. 26a-c).

There are some minor differences caused by the additional deposition of the auxiliary dummy semiconductor material 141. As shown in the enlargement in the inset of FIG. 22b, the oxidation of the auxiliary dummy semiconductor material 141 may be partial, such that there remains a non-oxidized thickness portion 141′ of the auxiliary dummy semiconductor material 141 upon completion of the oxidation process. Accordingly, the source/drain contact cavities 21, 22 may be separated from the gate stack 20 by the oxide liner 18 and the remaining non-oxidized thickness portion 141′. This similarly applies to the source/drain contacts 31, 32, as shown in FIG. 24b.

As further shown in FIGS. 25a-c and 26a -c, such remaining non-oxidized thickness portions 141′ may further be removed together with the first dummy semiconductor material, and replaced with material of the dielectric layer 34.

Additionally, regardless of whether the auxiliary dummy semiconductor material 141 is partial or complete, the oxide liner 18 in the second approach is preserved in the final device structure 1, as shown in FIGS. 26a-c, and hence provides a function of acting as an inner spacer between the source/drain contacts 31, 32 and the gate stack 20.

Resulting device structures 1 as shown in either of FIGS. 17a-c and/or 26a -c have a common or shared gate stack. By forming one of the transistors as a P-type FET and the other as an N-type FET, the device structure 1 may implement a CMOS inverter.

The illustrated process steps of the first and second approaches may (e.g., each) be followed with additional device fabrication steps, such as capping of the source/drain contacts and/or gate stack 20, middle-end-of line processing to form local interconnects, back-end-of-line processing, and/or the like.

The present disclosure is not limited to the examples described above. On the contrary, many modifications and variations are possible within the scope of the appended claims.

For example, while FIGS. 2a-c show how the channel layers 10 are (e.g., fully) encapsulated by respective dielectric layers 11, it is also possible to cap the channel layers 10 (e.g., only) along the lateral walls of the device layer stack 4 such that the end portions 10a, 10b of the channel layers 10 remain laid bare. This may be achieved by masking the end walls the device layer stack 10 facing the first and second source/drain sides S1, S2 with a temporary mask layer during the recess step, such that the channel layer 10, and optionally dielectric layers 9, are laterally etch backed back (e.g., only) from lateral walls of the device layer stack 4. Doing so, the recessing of the gate dielectric layer 11 prior to forming the source/drain contacts 31, 32, as shown in FIGS. 13a-c and FIGS. 22a-c, may be obviated.

Furthermore, the method of the present disclosure may be applied to a device layer stack (e.g., initially) including no gate dielectric layers, but simply an alternating stack of sacrificial layers (corresponding to sacrificial layers 6) and channel layers (corresponding to channel layers 10). The oxide liner may be formed as discussed above, after removing the sacrificial layers. A gate dielectric may (e.g., subsequently) be formed to surround the channel layers as part of forming the gate stack.

Furthermore, in the illustrated examples, the gate cavity 16 extends across the device layer stack 4 so as to expose both lateral walls of the device layer stack 4. This facilitates forming of a device with a gate stack of a GAA configuration. A gate stack of a GAA configuration has a non-zero gate extension on either lateral side of the channel region of the device. However, in other examples, the gate cavity 16 may be formed to expose (e.g., only) one of the lateral walls of the device layer stack 4. This facilitates forming of a device of a gate stack of “forksheet” gate configuration. A gate stack of a forksheet has a non-zero gate extension on (e.g., only) one lateral side of the channel region of the device and a zero or substantially zero gate extension on the opposite lateral side of the channel region. A forksheet configuration provides aggressive scaling of the device separation at the p-n boundary.

While some embodiments have been illustrated and described in detail in the appended drawings and the foregoing description, such illustration and description are to be considered illustrative and not restrictive. Other variations to the disclosed embodiments can be understood and effected in practicing the claims, from a study of the drawings, the disclosure, and the appended claims. The mere fact that certain measures or features are recited in mutually different dependent claims does not indicate that a combination of these measures or features cannot be used. Reference signs in the claims should not be construed as limiting the scope.

What is claimed is:

1. A method for forming a 2D channel field-effect transistor device, the method comprising:
forming a device layer stack on a substrate, the device layer stack including
a lower sacrificial layer and an upper sacrificial layer of a sacrificial material and
a channel layer of a 2D material arranged between the lower sacrificial layer and upper sacrificial layer, wherein the device layer stack extends in a first direction between a first source/drain side and a second source/drain side;
embedding the device layer stack in a dummy layer of a dummy semiconductor material;
forming a gate cavity in the dummy layer, the gate cavity extending in a second direction transverse to the first direction, and exposing the device layer stack along a channel region between the first and second source/drain side;
removing the lower and upper sacrificial layers from the device layer stack by selectively etching the sacrificial material from the gate cavity;
after removing the lower and upper sacrificial layers, forming an oxide liner along sidewalls of the gate cavity, wherein forming the oxide liner includes performing an oxidation process to oxidize a thickness portion of the dummy layer along the sidewalls of the gate cavity;
forming a gate stack in the gate cavity to surround the channel layer along the channel region, wherein the oxide liner separates the gate stack from the dummy layer;
forming source/drain contact cavities in the dummy layer on the first and second source/drain sides;
forming source/drain contacts in the source/drain contact cavities in contact with the channel layer; and
after forming the source/drain contacts, replacing the dummy layer with a dielectric layer.

2. The method according to claim 1, wherein the oxidation process is a plasma oxidation process.

3. The method according to claim 1, wherein the oxidation process is a room-temperature plasma oxidation process.

4. The method according to claim 1,
wherein the gate cavity includes first and second opposite sidewalls extending along the first and second source/drain sides, respectively, and third and fourth opposite sidewalls connecting the first and second sidewalls at opposite ends of the gate cavity, and
wherein the oxide liner is formed to extend along the first, second, third, and fourth sidewalls of the gate cavity.

5. The method according to claim 4,
wherein the third sidewall connects to the first and second sidewalls in respective corner regions of the gate cavity.

6. The method according to claim 5,
wherein the source/drain contact cavities are formed along the first and second sidewalls of the gate cavity, adjacent at least one of the respective corner regions.

7. The method according to claim 6, wherein at least one of the source/drain contact cavities extends past the respective corner region.

8. The method according to claim 1, wherein the device layer stack further includes a gate dielectric layer encapsulating the channel layer, wherein the gate dielectric layer and the channel layer are between the lower sacrificial layer and upper sacrificial layer.

9. The method according to claim 8, wherein forming the device layer stack includes:
forming an initial device layer stack including, in sequence, the lower sacrificial layer, a lower gate dielectric layer portion, the channel layer, an upper gate dielectric layer portion and the upper sacrificial layer;
forming a recess in the initial device layer stack by etching back at least the channel layer, and the gate dielectric layer portions; and
forming a side gate dielectric layer portion in the recess, wherein the side gate dielectric layer portion connects the upper gate and lower gate dielectric layer portions to form the gate dielectric layer encapsulating the channel layer.

10. The method according to claim 8, wherein the channel layer includes a first end portion facing the first source/drain side and a second end portion facing the second source/drain side.

11. The method according to claim 10, further including recessing the gate dielectric layer from the source/drain contact cavities to expose the first and second end portions of the channel layer, wherein the source/drain contacts are formed in the source/drain contact cavities, in contact with the exposed first and second end portions of the channel layer.

12. The method according to claim 1, further including:
after removing the lower and upper sacrificial layers and prior to forming the oxide liner, extending the dummy layer by selectively growing an auxiliary dummy semiconductor material on the dummy layer, including on the sidewalls of the gate cavity.

13. The method according to claim 12, wherein
the sidewalls of the gate cavity include a first sidewall extending along the first source/drain side and a second sidewall extending along the second source/drain side,
the channel layer includes a first end portion facing the first source/drain side and a second end portion facing the second source/drain side,
the auxiliary dummy semiconductor material grows laterally from the first and second sidewalls to surround the first and second end portions of the channel layer from above and below, and
the thickness portion of the dummy layer oxidized when performing the oxidation process includes a thickness portion of the auxiliary dummy semiconductor material.

14. The method according to claim 12, wherein the source/drain contact cavities in the dummy layer are separated from the gate stack by the oxide liner and a non-oxidized thickness portion of the auxiliary dummy semiconductor material.

15. The method according to claim 14, wherein replacing the dummy layer with a dielectric layer includes removing the dummy layer, including the non-oxidized thickness portion, using a selective etching process, and depositing the dielectric layer.

16. The method according to claim 11, further including, after forming the source/drain contact cavities and prior to forming the source/drain contacts,
recessing the oxide liner from the source/drain contact cavities to expose sidewall portions of the gate stack and recessing the exposed sidewall portions of the gate stack, to form source/drain recesses.

17. The method according to claim 16, further including
forming inner spacers covering the recessed sidewall portions of the gate stack and filling the source/drain recesses.

18. The method according to claim 17, wherein the gate dielectric layer is recessed to expose the first and second end portions of the channel layer.

19. The method according to claim 1, wherein the 2D channel material is a transition metal dichalcogenide.

20. The method according to claim 19, wherein the transition metal dichalcogenide is at least one of molybdenum disulfide, tungsten disulfide, molybdenum diselenide, or tungsten diselenide.
